(19) United States
(12) Patent Application Publication
(10) Pub. No.: US 2024/0421053 A1
(43) Pub. Date: Dec. 19, 2024

(54) PACKAGED DEVICE HAVING AN INTEGRATED PASSIVE DEVICE WITH WAFER LEVEL FORMED CONNECTION TO AT LEAST ONE SEMICONDUCTOR DEVICE AND PROCESSES FOR IMPLEMENTING THE SAME

(71) Applicant: WOLFSPEED, INC., Durham, NC (US)

(72) Inventors: Qianli MU, Durham, NC (US); Heather BARTON, Durham, NC (US); Basim NOORI, Durham, NC (US); Dan NAMISHIA, Wake Forest, NC (US); Dan ETTER, Durham, NC (US); Alexander KOMPOSCH, Morgan Hill, CA (US)

(21) Appl. No.: 18/334,527

(22) Filed: Jun. 14, 2023

(51) Int. Cl. H01L 23/498; H01L 23/00; H01L 23/14; H01L 23/58

(52) U.S. Cl. CPC H01L 23/49811; H01L 23/14; H01L 23/58; H01L 24/06; H01L 24/13; H01L 2021/60232; H01L 2224/05147; H01L 2224/0603; H01L 2224/13028

(57) ABSTRACT

A device includes at least one integrated passive device having at least one bond pad; at least one semiconductor device having at least one bond pad; and at least one connection structure arranged on the at least one integrated passive device. Additionally, the at least one connection structure includes a solder portion configured to form a solder connection to the at least one bond pad of the at least one semiconductor device.

### FIELD OF THE DISCLOSURE

The disclosure is directed to a packaged device having an integrated passive device with at least one wafer level formed connection to at least one semiconductor device. The disclosure is further directed to processes for implementing a packaged device having an integrated passive device with at least one wafer level formed connection to at least one semiconductor device.

### BACKGROUND OF THE DISCLOSURE

Current flip chip technology is typically implemented by processing bumps on a semiconductor wafer, such as a Gallium nitride silicon carbide (GaNSiC) wafer, for attachment to another device. The current process capability is limited by the wafer size, which is usually 4 or 6 inches. It is also challenging to process within semiconductor wafers, such as thin GaNSiC wafers, with flip chip technology due to process capability limitations and material properties of silicon carbide (SiC).

Accordingly, what is needed are processes and configurations to address process capability limitations and material properties of SiC.

### SUMMARY OF THE DISCLOSURE

In one aspect, a packaged device includes at least one integrated passive device having at least one bond pad. The packaged device in addition includes at least one semiconductor device having at least one bond pad. The device moreover includes at least one connection structure arranged on the at least one integrated passive device. The device also includes where the at least one connection structure includes a solder portion configured to form a solder connection to the at least one bond pad of the at least one semiconductor device.

In one aspect, a process includes configuring at least one integrated passive device with at least one bond pad. The process in addition includes configuring at least one semiconductor device with at least one bond pad. The process moreover includes arranging at least one connection structure on the at least one integrated passive device. The process also includes arranging a solder portion on the at least one connection structure. The process further includes connecting the at least one connection structure to the at least one bond pad of the at least one semiconductor device with the solder portion.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a cross-sectional view of a packaged device according to aspects of the disclosure.

FIG. 2 illustrates a partial cross-sectional view of the at least one integrated passive device as well as details of the at least one bond pad and the at least one connection structure according to aspects of the disclosure.

FIG. 3 illustrates a partial cross-sectional view of the at least one semiconductor device as well as details of the at least one bond pad according to aspects of the disclosure.

FIG. 4 illustrates another partial cross-sectional view of the at least one semiconductor device as well as details of the at least one bond pad according to aspects of the disclosure.

FIG. 5 illustrates an exemplary process flow for forming the at least one bond pad and the at least one connection structure of the at least one integrated passive device according to aspects of the disclosure.

FIG. 6 illustrates an initial configuration of the at least one integrated passive device according to FIG. 5.

FIG. 7 illustrates a seed metal deposition configuration of the at least one integrated passive device according to FIG. 5.

FIG. 8 illustrates a photopatterned configuration of the at least one integrated passive device according to FIG. 5.

FIG. 9 illustrates a plated configuration of the at least one integrated passive device according to FIG. 5.

FIG. 10 illustrates a photopattern stripped configuration of the at least one integrated passive device according to FIG. 5.

FIG. 11 illustrates a seed metal stripped configuration of the at least one integrated passive device according to FIG. 5.

FIG. 12 illustrates a reflowed configuration of the at least one integrated passive device according to FIG. 5.

FIG. 13 illustrates an exemplary process flow for forming the at least one bond pad of the at least one semiconductor device according to aspects of the disclosure.

FIG. 14 illustrates an initial configuration of the at least one semiconductor device according to FIG. 13.

FIG. 15 illustrates a seed metal deposition configuration of the at least one semiconductor device according to FIG. 13.

FIG. 16 illustrates a photopatterned configuration of the at least one semiconductor device according to FIG. 13.

FIG. 17 illustrates a plated configuration of the at least one semiconductor device according to FIG. 13.

FIG. 18 illustrates a photopattern stripped configuration of the at least one semiconductor device according to FIG. 13.

FIG. 19 illustrates a seed metal stripped configuration of the at least one semiconductor device according to FIG. 13.

FIG. 20 illustrates exemplary wafer level processing of a wafer of the at least one integrated passive device according to aspects of the disclosure.

FIG. 21 further illustrates the exemplary wafer level processing of a wafer of the at least one integrated passive device according to aspects of the disclosure.

FIG. 22 illustrates another exemplary wafer level processing of a wafer of the at least one integrated passive device.

FIG. 23 illustrates a cross-sectional view of another implementation of the packaged device according to aspects of the disclosure.

FIG. 24 illustrates a cross-sectional view of another implementation of the packaged device according to aspects of the disclosure.

FIG. 25 illustrates a cross-sectional view of another implementation of the packaged device according to aspects of the disclosure.

FIG. 26 illustrates a cross-sectional view of another implementation of the packaged device according to aspects of the disclosure.

FIG. 27 illustrates a cross-sectional view of another implementation of the packaged device according to aspects of the disclosure.

FIG. 28 illustrates a cross-sectional view of another implementation of the packaged device according to aspects of the disclosure.

FIG. 29 illustrates a cross-sectional view of the at least one integrated passive device according to aspects of the disclosure.

FIG. 30 illustrates a cross-sectional view of another implementation of the packaged device according to aspects of the disclosure.

FIG. 31 illustrates exemplary wafer level processing of a wafer of the at least one integrated passive device according to aspects of the disclosure.

FIG. 32 illustrates a cross-sectional view of another implementation of the packaged device according to aspects of the disclosure.

FIG. 33 shows an exemplary process of implementing a packaged device according to aspects of the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects, as the skilled artisan would recognize, even if not explicitly stated herein. Descriptions of well-known components and processing techniques may be omitted so as not to unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings and in the different embodiments disclosed.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The disclosure enables stacking an active device, such as a Gallium nitride silicon carbide (GaNSiC) transistor, on an integrated passive device (IPD) chip or interposer, such as SiC-IPD, and provides a way to realize wafer level packaging for applications, such as RF power applications. The stack up helps to achieve good radio frequency (RF) performance, thermal performance, and/or the like. The disclosed approach also offers a way to bump the active devices, such as thin GaNSiC chips, and reduce assembly and manufacturing cost.

Current flip chip technology is typically implemented by processing bumps on a semiconductor wafer, such as a Gallium nitride silicon carbide (GaNSiC) wafer, for attachment to another device. The current process capability is limited by the wafer size, which is usually 4 or 6 inches. It is also challenging to process within semiconductor wafers, such as thin GaNSiC wafers, with flip chip technology due to process capability limitations and material properties of silicon carbide (SIC).

By changing the GaNSiC bond pad metal stack up and making it compatible with a soldering reflow process, the disclosed device and process allows attaching thin GaNSiC dies, like 75 or 100 μm dies, onto an IPD wafer through bumping. Such approach allows bumps processed on a 6 or 8 inch IPD wafer, which may be based on SiC wafer or silicon (Si) wafer. By attaching the GaNSiC dies on the IPD wafer first, then singulation, the disclosed process provides a way to achieve wafer level packaging, which helps to reduce manufacturing cost, improve product yield, and/or the like.

Aspects of the disclosed process and device may utilize wafer level processing (WLP) to form one or more bumps or copper pillars on IPD wafers. In aspects, the disclosed process may include first bumping the SiC IPD. In aspects of the disclosure, the processing may begin with under bump metals (UBM), depositing seed metal such as titanium (Ti), Tungsten-titanium (TiW), and/or the like for adhesion, followed by copper (Cu) for electrical continuity.

In aspects, the one or more bumps or copper pillars may be implemented as electroplated bumps or pillars. For electroplated bumps or pillars, the wafer may be photopatterned to create a plating template.

In aspects for implementation of the one or more bumps or copper pillars with solders, the plating may generally include an approximately 2 μm nickel (Ni) barrier under or immediately under the solder to prevent metal migration.

In the case of Cu pillars, the Cu pedestal may be plated in the same template prior to plating Ni and solder. Once the bumps or pillars are plated, a resist may be stripped in a solvent and a blanket seed metal may be etched back to clear the field. Thereafter, the disclosed process may implement reflow of the plated solder to form domed bumps ready for bonding.

Aspects of the disclosed process and device may utilize WLP for forming pads, such as Ni pads, gold (Au) pads, and/or the like on the active device wafer, such as GaNSiC wafers.

In aspects, the GaNSiC wafers may be processed to form complementary bond pads to the bumped structures on the IPD device. In aspects, the disclosed process can be accomplished using similar processing to the IPD device. For example, depositing seed metal such as titanium (Ti), Tungsten-titanium (TiW), and/or the like for adhesion, followed by copper (Cu) for electrical continuity. Thereafter, the GaNSiC may be photopatterned. Further, the pads, such as Ni pads and/or Au pads are electroplated in the template. In aspects, the Ni pads may be approximately 2 μm and the Au pads may be approximately 0.25 μm.

Thereafter, the resist and the seed metal may then be stripped back in the same fashion as the IPD. The choice of Ni pad thickness may be based on the need for a barrier to metal migration; and a choice of Au pad thickness may be based on a need to prevent oxidation and allow for proper wetting to the solder during die attach. In other aspects, these pads may be deposited using electroless plating baths, which may eliminate the need for seed metal or seed metal strip.

Aspects of the disclosed device and process may further utilize hybridization, molding, singulation, and/or the like of resulting assemblies, such as GaNSiC-IPD assemblies.

In aspects, upon completion of all wafer level processing of the active device, such as the GaNSiC device, the wafers may then be diced. Individual active device die, such as GaNSiC die may be aligned to a full IPD wafer to allow for wafer level reflow, a batch die attach process, and/or the like.

Following die attach, it may be beneficial to apply an epoxy to structurally support the bond and lock the die in place. This can be accomplished using a number of methods.

In one exemplary method, the die can be molded to the wafer using vacuum assisted molding. This may create a blanket, void-free encapsulation of the die attached to the IPD wafer. For this method, the IPD wafer dicing may include dicing through the wafer level molding.

Alternatively, the active die, such as the GaNSiC die, can be individually underfilled using capillary underfill, relying on natural capillary vacuum to draw the underfill epoxy only through a bond line of the die. In this aspect, dicing streets of the IPD wafer may be left clear for standard SiC dicing.

Aspects of the disclosed device and process may utilize multiple active die, such as multiple GaNSiC dies, on an IPD interposer after singulation. Such implementations may be design dependent. The assembly may then be incorporated into a full package using solder bumps.

Aspects of the disclosed device and process may implement single or multiple die, such as single or multiple GaNSiC dies on an IPD chip or interposer. In aspects, the chips may include bumps on interconnect pads to allow stacked chips connecting to a next level package. In aspects, solder paste printing may be used on the package for connecting. When such assembly flow is used, bumps on stacked chip interconnect pads may not be required.

In aspects, the SiC IPD or Si IPD may be attached to a circuit board (PCB), for example by solder bumps. In aspects, the assembly may be aligned such that the active device back side, such as a GaNSiC device backside, contacts a heat sink or flange with a conductive adhesive.

In aspects, an integrated package product may have the SiC or Si IPD attached to a PCB via solder bumps. The assembly would be aligned such that the GaNSiC backside contacts a heat sink or flange with a conductive adhesive.

Aspects of the disclosed process and device may be utilized for any applications, such as any RF power applications, which may benefit from vertical integration for better electrical performance, thermal performance, and/or the like.

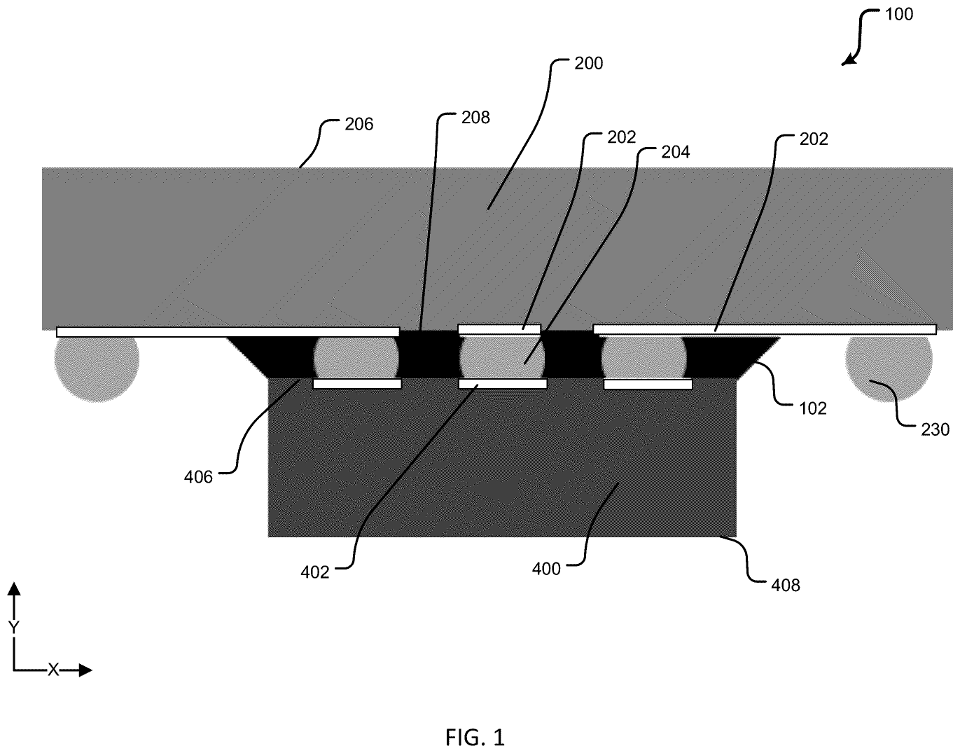

FIG. 1 illustrates a cross-sectional view of a packaged device according to aspects of the disclosure.

In particular, FIG. 1 illustrates a cross-sectional view of a packaged device 100 according to aspects of the disclosure. The packaged device 100 may include at least one integrated passive device 200 and at least one semiconductor device 400. The at least one semiconductor device 400 may include at least one bond pad 402 and the at least one integrated passive device 200 may include at least one bond pad 202.

The disclosure enables stacking the at least one semiconductor device 400, such as a Gallium nitride silicon carbide (GaNSiC) transistor, on the at least one integrated passive device 200, such as an integrated passive device (IPD) chip, printed circuit board (PCB), and/or the like, such as SiC-IPD, and provides a way to realize wafer level packaging for applications, such as RF power applications. The stack up helps to achieve good radio frequency (RF) performance, thermal performance, and/or the like. The disclosed approach also offers a way to bump the at least one semiconductor device 400, such as thin GaNSiC chips, and reduce assembly and manufacturing cost.

Additionally, the at least one integrated passive device 200 may include at least one connection structure 204. In aspects, the at least one connection structure 204 may be a bump, bumps, bumping, a pillar, pillars, and/or the like as further described herein. The at least one connection structure 204 may connect the at least one bond pad 202 of the at least one integrated passive device 200 to the at least one bond pad 402 of the at least one semiconductor device 400.

In particular aspects, a connectivity for the at least one semiconductor device 400 on the at least one integrated passive device 200 may be provided on a side of the at least one integrated passive device 200 and not a side of the at least one semiconductor device 400. In this regard, the at least one semiconductor device 400 may be implemented as a flip chip attachment configuration on the at least one integrated passive device 200. The subsequent configuration of the at least one integrated passive device 200 and the at least one semiconductor device 400 may be implemented in a number of different configurations such as those described herein as well as many others. In aspects, the at least one bond pad 402 arranged on the at least one semiconductor device 400 may be bumping compatible. In other words, the at least one bond pad 402 may be compatible with the at least one connection structure 204 arranged on the at least one integrated passive device 200.

In aspects, the at least one integrated passive device 200 may be initially formed in a wafer. In this regard, the wafer may include a plurality of implementations of the at least one integrated passive device 200 formed therein. The wafer may be a silicon wafer or a silicon carbide wafer. Further, a number of features of the at least one integrated passive device 200 may be structured and/or arranged with the at least one integrated passive device 200 while still part of the wafer. In this regard, structuring and/or arranging features with the at least one integrated passive device 200 while still part of the wafer is defined as wafer level processing (WLP).

In particular aspects, the at least one connection structure 204 of the at least one integrated passive device 200 may be structured and/or arranged with the at least one integrated passive device 200 while the at least one integrated passive device 200 is still part of the wafer. Accordingly, the at least one connection structure 204 may be formed during wafer level processing (WLP).

In particular aspects, the at least one semiconductor device 400 may be structured and/or arranged with the at least one integrated passive device 200 while the at least one integrated passive device 200 is still part of the wafer. Accordingly, the at least one semiconductor device 400 may be attached to the at least one integrated passive device 200 during wafer level processing (WLP).

In particular aspects, the at least one semiconductor device 400 may be attached to the at least one connection structure 204 of the at least one integrated passive device 200 while the at least one integrated passive device 200 is still part of the wafer. Accordingly, the at least one semiconductor device 400 may be attached to the at least one connection structure 204 of the at least one integrated passive device 200 during wafer level processing (WLP).

Thereafter, the wafer that includes the at least one integrated passive device 200 that includes the at least one semiconductor device 400 and the at least one connection structure 204 may be singulated to form the resulting implementation of the at least one integrated passive device 200 that may be implemented with the packaged device 100.

Additionally, the packaged device 100 may include a packaging compound 102. Further, the packaging compound 102 may be arranged between the at least one integrated passive device 200 and/or the at least one semiconductor device 400 as described herein during wafer level processing (WLP).

In aspects, the packaging compound 102 may be an epoxy, a molding material, a mold compound, and/or the like. As illustrated in FIG. 1, the packaged device 100 may be configured such that the packaging compound 102 may be arranged between the at least one integrated passive device 200 and the at least one semiconductor device 400. In aspects, the packaging compound 102 may be configured as an underfill between the at least one integrated passive device 200 and the at least one semiconductor device 400. In aspects, the packaging compound 102 may surround one or more implementations of the at least one connection structure 204. In aspects, the packaging compound 102 may surround all implementations of the at least one connection structure 204.

Further, the packaged device 100 may include at least one solder ball connection 230. In aspects, the at least one solder ball connection 230 may be arranged on an implementation of the at least one bond pad 202. As illustrated in FIG. 1, the at least one solder ball connection 230 may be attached to an elongated configuration of the at least one bond pad 202 that also connects to an implementation of the at least one connection structure 204.

In aspects, the at least one bond pad 402 of the at least one semiconductor device 400 may be arranged on an upper surface 406 of the at least one semiconductor device 400 opposite a lower surface 408 of the at least one semiconductor device 400.

In aspects, the at least one bond pad 202 of the at least one integrated passive device 200 may be arranged on a first surface 208 of the at least one integrated passive device 200 opposite a second surface 206 of the at least one integrated passive device 200. In aspects, the at least one integrated passive device 200 may be configured as a flip chip. Accordingly, the at least one integrated passive device 200 may initially configure and arrange the first surface 208 as an upper surface during WLP. Thereafter, the at least one integrated passive device 200 may be flipped such that the first surface 208 is oriented as a lower surface. In other aspects, the at least one integrated passive device 200 may be configured as a non-flip chip.

In aspects, the at least one connection structure 204 may be arranged on the at least one bond pad 202 on the first surface 208 of the at least one integrated passive device 200. Further, the at least one connection structure 204 may be configured to extend vertically to the at least one integrated passive device 200 and/or the at least one bond pad 202. In aspects, the at least one connection structure 204 may be configured to connect to the at least one bond pad 402 of the at least one semiconductor device 400.

In aspects, the at least one connection structure 204 may be configured to connect to the at least one bond pad 402 of the at least one semiconductor device 400 by solder. In aspects, the at least one connection structure 204 may form a solder connection, a reflowed solder connection, and/or the like to the at least one bond pad 402 of the at least one semiconductor device 400. In other aspects, the at least one connection structure 204 may be configured to connect to the at least one bond pad 402 of the at least one semiconductor device 400 by adhesive, sintering, eutectic bonding, ultrasonic welding, and/or the like.

In aspects, the at least one semiconductor device 400 may be implemented as a transistor, a silicon carbide (SiC) transistor, a Gallium nitride silicon carbide (GaNSiC) transistor, and/or the like. In aspects, the at least one integrated passive device 200 may be implemented as an integrated passive device (IPD) chip, a SiC-IPD chip, a SiC-IPD, an interposer, an IPD interposer, a SiC-IPD interposer, and/or the like.

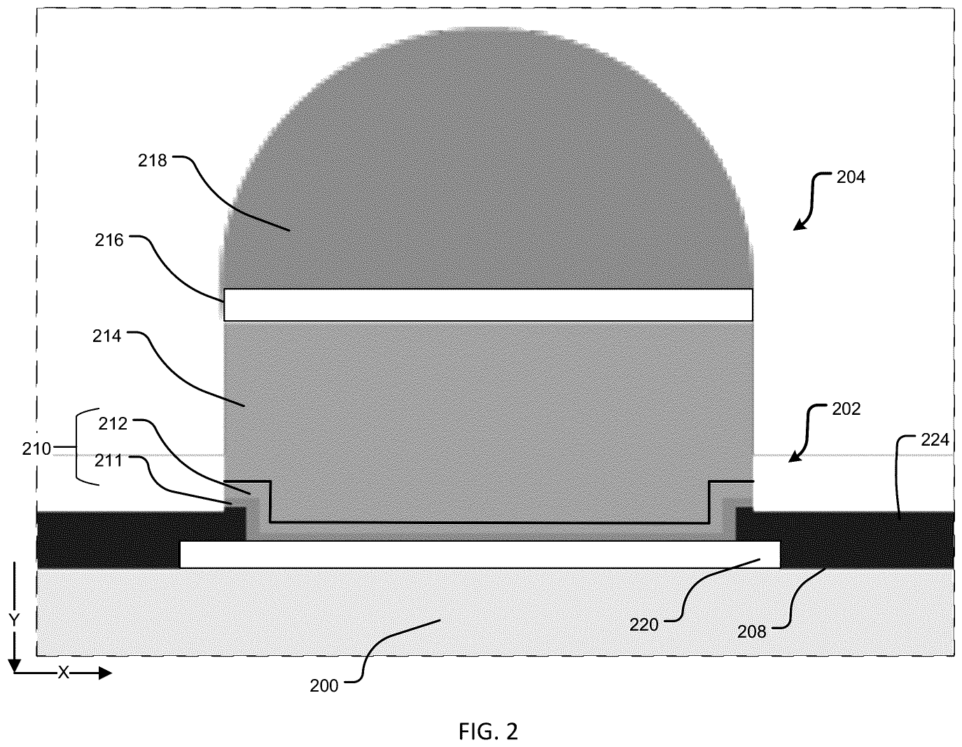

FIG. 2 illustrates a partial cross-sectional view of the at least one integrated passive device as well as details of the at least one bond pad and the at least one connection structure according to aspects of the disclosure.

In particular, FIG. 2 illustrates a partial cross-sectional view of the at least one integrated passive device 200 as well as details of the at least one bond pad 202 and the at least one connection structure 204 according to aspects of the disclosure. As illustrated in FIG. 2, the at least one integrated passive device 200 is shown inverted for ease of understanding. In this regard, the at least one integrated passive device 200 may be configured as a flip chip and may be subsequently inverted that shown in FIG. 1 when combined with the packaged device 100.

As further illustrated in FIG. 2, the at least one bond pad 202 may be arranged on the first surface 208 of the at least one integrated passive device 200 and/or a metallization layer 220 on the first surface 208 of the at least one integrated passive device 200. In aspects, the metallization layer 220 may be formed of a metallic material such as copper, gold, nickel, palladium, silver, aluminum, tin, alloys thereof, combinations thereof, and/or the like. Additionally, the at least one connection structure 204 may be arranged on the at least one bond pad 202. In aspects, the at least one connection structure 204 may be implemented as one or more bumps, copper bumps, pillars, copper pillars, and/or the like arranged on the at least one bond pad 202.

In aspects, the at least one bond pad 202 may include one or more under bump metals (UBM) 210. In aspects, the one or more under bump metals (UBM) 210 may include any metallic materials. In particular aspects, the one or more under bump metals (UBM) 210 may include titanium (Ti), Tungsten-titanium (TiW), copper (Cu), and/or the like. In aspects, the at least one bond pad 202 and/or the one or more under bump metals (UBM) 210 may be formed of a metallic material such as copper, gold, nickel, palladium, silver, aluminum, tin, alloys thereof, combinations thereof, and/or the like.

In further aspects, the one or more under bump metals (UBM) 210 may include a first layer 211 arranged on the metallization layer 220 and a second layer 212 arranged on the first layer 211.

In aspects, the first layer 211 may be arranged directly on the metallization layer 220. In other aspects, the first layer 211 may be arranged on the metallization layer 220 with intervening layers.

In aspects, the second layer 212 may be arranged directly on the first layer 211. In other aspects, the second layer 212 may be arranged on the first layer 211 with intervening layers.

In aspects, the first layer 211 may include titanium (Ti), Tungsten-titanium (TiW), and/or the like for adhesion; and the second layer 212 may include copper (Cu) for electrical continuity.

In aspects, the one or more under bump metals (UBM) 210 may be formed by depositing the first layer 211 and the second layer 212 as a seed metal such as titanium (Ti), Tungsten-titanium (TiW), and/or the like for adhesion, followed by copper (Cu) for electrical continuity. In aspects, the depositing the first layer 211 and the second layer 212 may be implemented during WLP of the wafer of the at least one integrated passive device 200.

In aspects, the first layer 211 and the second layer 212 may be an etched structure. In this regard, the at least one integrated passive device 200 may include a passivation layer 224. The passivation layer 224 may be arranged on the first surface 208 of the at least one integrated passive device 200. Initially, the first layer 211 and the second layer 212 may extend across the passivation layer 224. Thereafter, the first layer 211 and the second layer 212 may be etched during WLP of the at least one integrated passive device 200 from portions of the passivation layer 224.

Additionally, the at least one connection structure 204 may include a pillar portion 214, a layer portion 216, and a solder portion 218. In aspects, the pillar portion 214 may be arranged directly on the second layer 212. In aspects, the pillar portion 214 may be arranged on the second layer 212 with intervening layers therebetween.

In aspects, the pillar portion 214 may be formed of any type of material. In aspects, the pillar portion 214 may be an electroplated metallic structure, an electroplated copper structure, a plated metallic structure, a plated copper structure, an electroless plated metallic structure, an electroless plated copper structure, and/or the like. In aspects, the pillar portion 214 may be implemented with a metallic bump, gold bump, a compression bonding structure, a golden compression bonding structure, a ball drop, a C4 (controlled collapse chip connection) bump, a microsphere, and/or the like. In aspects, the pillar portion 214 may be formed of a metallic material such as copper, gold, nickel, palladium, silver, aluminum, tin, alloys thereof, combinations thereof, and/or the like. In aspects, the pillar portion 214 may be formed during WLP of the at least one integrated passive device 200.

In aspects, the layer portion 216 may be arranged directly on the pillar portion 214. In aspects, the layer portion 216 may be arranged on the pillar portion 214 with intervening layers therebetween. In aspects, the layer portion 216 may be formed during WLP of the at least one integrated passive device 200.

In aspects, the solder portion 218 may be arranged directly on the layer portion 216. In aspects, the solder portion 218 may be arranged on the layer portion 216 with intervening layers therebetween. In aspects, the solder portion 218 may be formed during WLP of the at least one integrated passive device 200. In aspects, the solders may include various materials including Tin (Sn), gold (Ag), lead (Pb), and/or the like such as SnAg material based solder, leaded solders, AuSn material based solder, and/or the like.

In further aspects, prior to formation of the solder portion 218, the layer portion 216 and/or other portion of the at least one connection structure 204 may optionally be treated with flux. The flux may facilitate wetting of the solder portion 218, may act as an oxygen barrier by coating the layer portion 216 and/or the like. The flux may be applied to the layer portion 216 utilizing any known processing equipment. For example, the at least one integrated passive device 200 with the layer portion 216 formed thereon may be flipped and dipped into flux to apply the flux to the at least one connection structure 204 and/or the layer portion 216. In other aspects, the layer portion 216 and/or the at least one connection structure 204 may not be treated with flux.

In aspects, the layer portion 216 may be under or directly under the solder portion 218 to prevent metal migration. In aspects, the layer portion 216 may be a nickel (Ni) barrier arranged under or immediately under the solder portion 218 to prevent metal migration. In aspects, the layer portion 216 may be 1 to 3 μm in thickness along the y-axis. In aspects, the layer portion 216 may be approximately 2 μm in thickness along the y-axis.

In particular, the at least one connection structure 204 provides a connectivity between the at least one integrated passive device 200 and the at least one semiconductor device 400. In this regard, the at least one connection structure 204 may be arranged on the at least one integrated passive device 200, may be arranged on a side of the at least one integrated passive device 200, and/or the like. More specifically, according to aspects of the disclosure, the at least one connection structure 204 may not be arranged on the at least one semiconductor device 400, arranged on a side of the at least one semiconductor device 400, and/or the like. Accordingly, the solder portion 218 may be arranged closer to the at least one semiconductor device 400 than to the at least one integrated passive device 200.

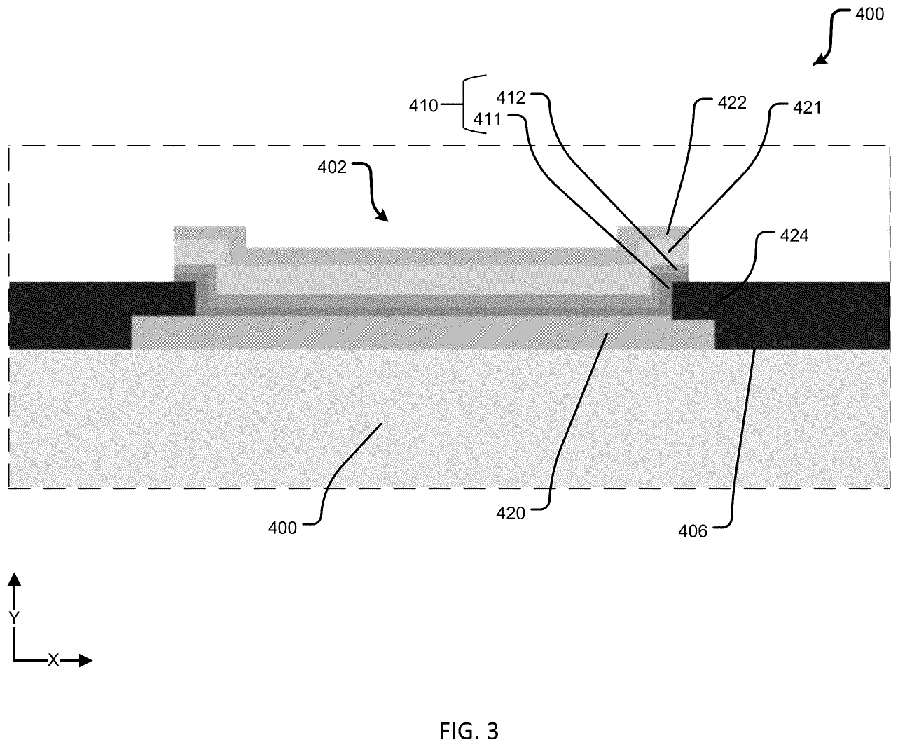

FIG. 3 illustrates a partial cross-sectional view of the at least one semiconductor device as well as details of the at least one bond pad according to aspects of the disclosure.

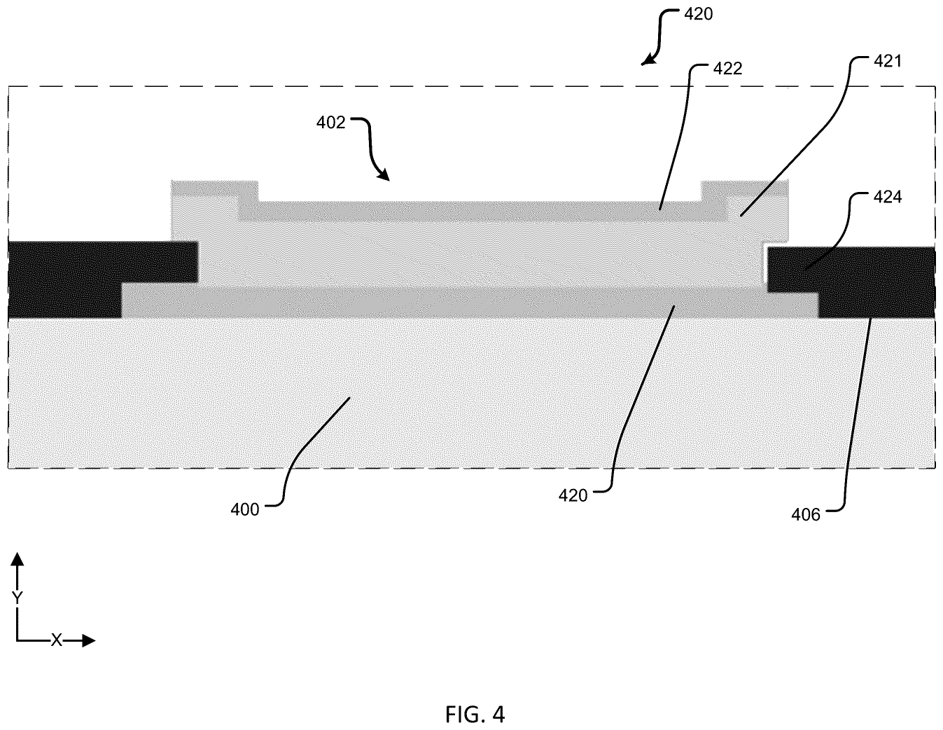

FIG. 4 illustrates another partial cross-sectional view of the at least one semiconductor device as well as details of the at least one bond pad according to aspects of the disclosure.

In particular, FIG. 3 illustrates a partial cross-sectional view of the at least one semiconductor device 400 as well as details of the at least one bond pad 402 according to aspects of the disclosure.

As further illustrated in FIG. 3, the at least one bond pad 402 may be arranged on the upper surface 406 of the at least one semiconductor device 400 and/or a metallization layer 420 on the upper surface 406 of the at least one semiconductor device 400. In aspects, the metallization layer 420 may be formed of a metallic material such as copper, gold, nickel, palladium, silver, aluminum, tin, alloys thereof, combinations thereof, and/or the like.

In aspects, the at least one bond pad 402 may include one or more under bump metals (UBM) 410. In aspects, the one or more under bump metals (UBM) 410 may include any metallic materials. In particular aspects, the one or more under bump metals (UBM) 410 may include titanium (Ti), Tungsten-titanium (TiW), copper (Cu), and/or the like. In aspects, the at least one bond pad 402 and/or the one or more under bump metals (UBM) 410 may be formed of a metallic material such as copper, gold, nickel, palladium, silver, aluminum, tin, alloys thereof, combinations thereof, and/or the like.

In further aspects, the one or more under bump metals (UBM) 410 may include a first layer 411 arranged on the metallization layer 420 and a second layer 412 arranged on the first layer 411.

In aspects, the first layer 411 may be arranged directly on the metallization layer 420. In other aspects, the first layer 211 may be arranged on the metallization layer 420 with intervening layers.

In aspects, the second layer 412 may be arranged directly on the first layer 411. In other aspects, the second layer 412 may be arranged on the first layer 411 with intervening layers.

In aspects, the first layer 411 may include titanium (Ti), Tungsten-titanium (TiW), and/or the like for adhesion; and the second layer 412 may include copper (Cu) for electrical continuity.

In aspects, the one or more under bump metals (UBM) 410 may be formed by depositing the first layer 411 and the second layer 412 as a seed metal such as titanium (Ti), Tungsten-titanium (TiW), and/or the like for adhesion, followed by copper (Cu) for electrical continuity. In aspects, the depositing the first layer 411 and the second layer 412 may take place during WLP of the at least one semiconductor device 400.

In aspects, the first layer 411 and the second layer 412 may be an etched structure. In this regard, the at least one semiconductor device 400 may include a passivation layer 424. The passivation layer 424 may be arranged on the upper surface 406 of the at least one semiconductor device 400. Initially, the first layer 411 and the second layer 412 may extend across the passivation layer 424. Thereafter, the first layer 411 and the second layer 412 may be etched during WLP of the at least one semiconductor device 400 from portions of the passivation layer 424.

Additionally, the at least one bond pad 402 may include at least one pad structure. In aspects, the at least one pad structure may include a metallic pad, an electroplated metallic pad, a Ni pad, an Au pad, an electroplated Ni pad, an electroplated Au pad, and/or the like.

In aspects, the at least one pad structure may include a first pad structure 421 and a second pad structure 422. The first pad structure 421 and/or the second pad structure 422 may include a metallic pad, an electroplated metallic pad, a Ni pad, an Au pad, an electroplated Ni pad, an electroplated Au pad, and/or the like.

In aspects, the first pad structure 421 may be arranged directly on the first layer 411. In aspects, the first pad structure 421 may be arranged on the first layer 411 with intervening layers therebetween.

In aspects, the second pad structure 422 may be arranged directly on the first pad structure 421. In aspects, the second pad structure 422 may be arranged on the first pad structure 421 with intervening layers therebetween.

In aspects, the first pad structure 421 may include a metallic pad, an electroplated metallic pad, a Ni pad, an electroplated Ni pad, and/or the like. In aspects, the second pad structure 422 may include a metallic pad, an electroplated metallic pad, an Au pad, an electroplated Au pad, and/or the like.

In particular aspects, the at least one semiconductor device 400 may be photopatterned to form a template having a resist. Further, the first pad structure 421 and the second pad structure 422 may be electroplated on the second layer 412 in the template. In aspects, the first pad structure 421 and the second pad structure 422 may be configured during WLP of the at least one semiconductor device 400.

In aspects, the first pad structure 421 may be formed of as a Ni pad that may be 1 to 3 μm in thickness along the y-axis; and the second pad structure 422 may be formed as an Au pad that may be 0.1 μm to 0.5 μm in thickness along the y-axis. In aspects, the first pad structure 421 may be formed of as a Ni pad that may be approximately 2 μm in thickness along the y-axis and the second pad structure 422 may be formed as an Au pad that may be approximately 0.25 μm in thickness along the y-axis.

Thereafter, the resist and the seed metal that includes the first layer 411 and the second layer 412 may then stripped back from the at least one semiconductor device 400 in the same fashion as the at least one integrated passive device 200. The choice of Ni pad thickness of the first pad structure 421 may be based on the need for a barrier to metal migration; and a choice of Au pad thickness of the second pad structure 422 may be based on a need to prevent oxidation and allow for proper wetting to the solder portion 218 of the at least one connection structure 204.

In other aspects illustrated in FIG. 4, the first pad structure 421 and the second pad structure 422 may be deposited using electroless plating baths. In this aspect, the first pad structure 421 and the second pad structure 422 may be deposited using electroless plating baths during WLP of the at least one semiconductor device 400. Implementation of electroless plating may eliminate the need for seed metal or seed metal strip, such as may be needed for implementation the first layer 411 and the second layer 412 illustrated in FIG. 3.

In aspects, the first pad structure 421 may be directly attached to the metallization layer 420. In aspects, the first pad structure 421 may be attached to the metallization layer 420 with intervening layers therebetween.

The disclosed implementation of the packaged device 100 may enable stacking of the at least one integrated passive device 200 and the at least one semiconductor device 400 in a configuration to realize wafer level packaging for applications, such as RF power applications. The stack up of the at least one integrated passive device 200 and the at least one semiconductor device 400 of the packaged device 100 may help to achieve good radio frequency (RF) performance, thermal performance, and/or the like. Further, the disclosed implementation of the packaged device 100 may offer a way to bump the at least one semiconductor device 400, such as thin GaNSiC chips implementations of the at least one semiconductor device 400 and reduce assembly cost, manufacturing cost, and/or the like of the packaged device 100.

Further, configuring and implementing the at least one bond pad 402 of the at least one semiconductor device 400 with the disclosed bond pad metal stack up configured as the at least one bond pad 402 to be compatible with a soldering reflow process. In this regard, the disclosed implementation of the packaged device 100 and associated process allows attaching the at least one semiconductor device 400, which may be implemented as thin GaNSiC dies, like 75 or 100 μm dies, onto an IPD wafer that includes the at least one integrated passive device 200 through bumping. Such approach allows bumps processed on a 6 or 8 inch IPD wafer, which may be based on SiC wafer or silicon (Si) wafer. By attaching the at least one semiconductor device 400 on the IPD wafer of the at least one integrated passive device 200 first, then singulation, the disclosed process provides a way to achieve wafer level packaging which helps to reduce manufacturing cost, improve product yield, and/or the like.

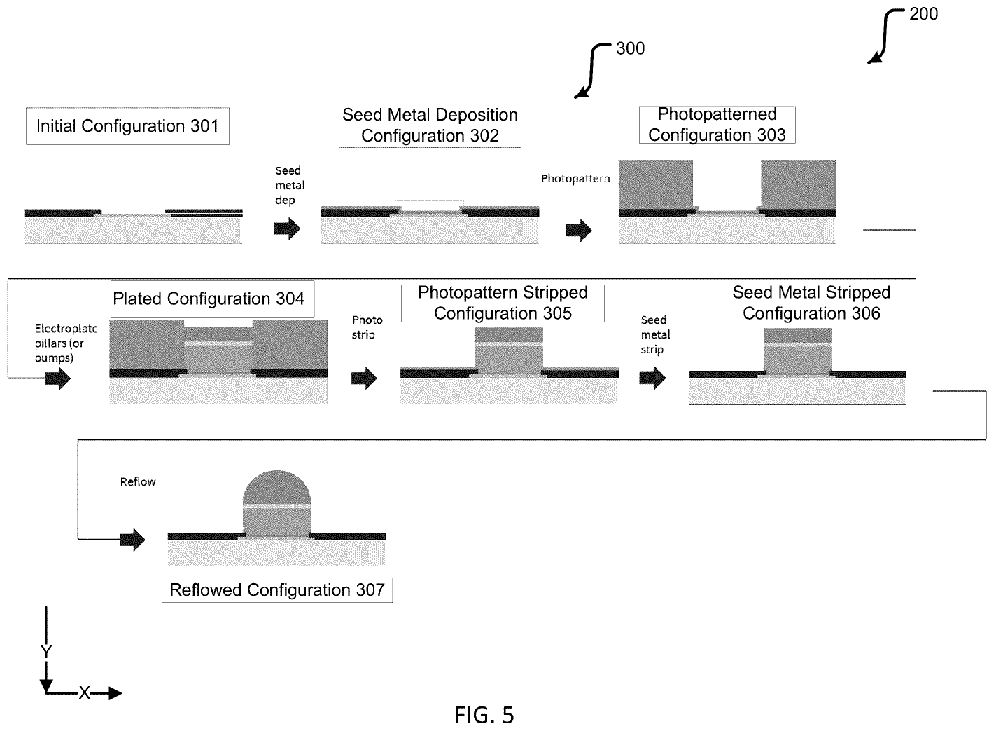

FIG. 5 illustrates an exemplary process flow for forming the at least one bond pad and the at least one connection structure of the at least one integrated passive device according to aspects of the disclosure.

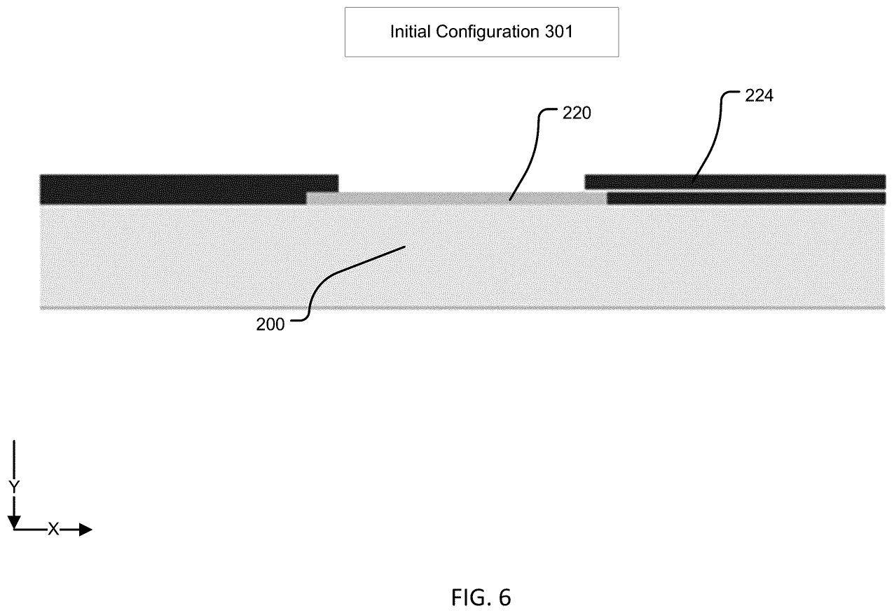

FIG. 6 illustrates an initial configuration of the at least one integrated passive device according to FIG. 5.

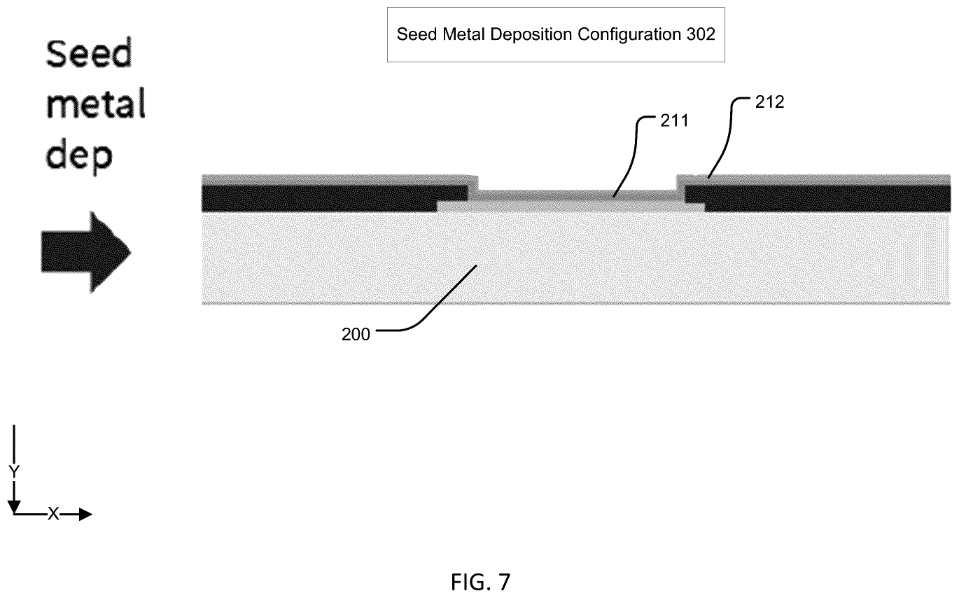

FIG. 7 illustrates a seed metal deposition configuration of the at least one integrated passive device according to FIG. 5.

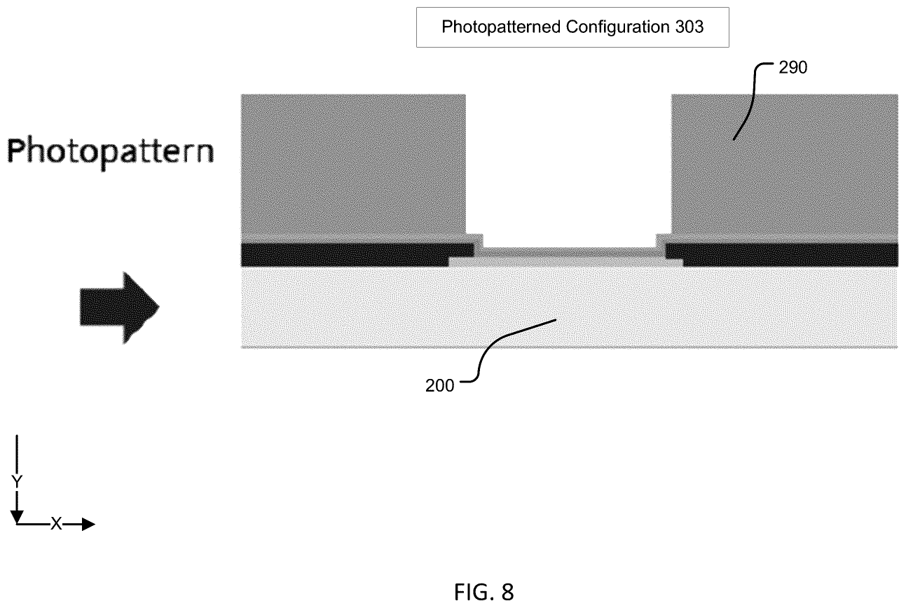

FIG. 8 illustrates a photopatterned configuration of the at least one integrated passive device according to FIG. 5.

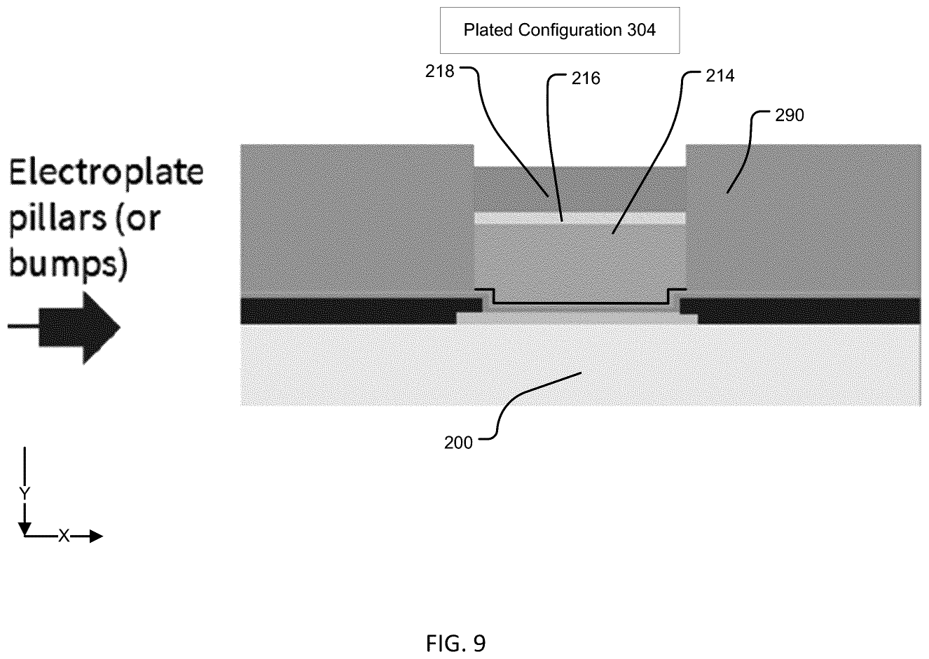

FIG. 9 illustrates a plated configuration of the at least one integrated passive device according to FIG. 5.

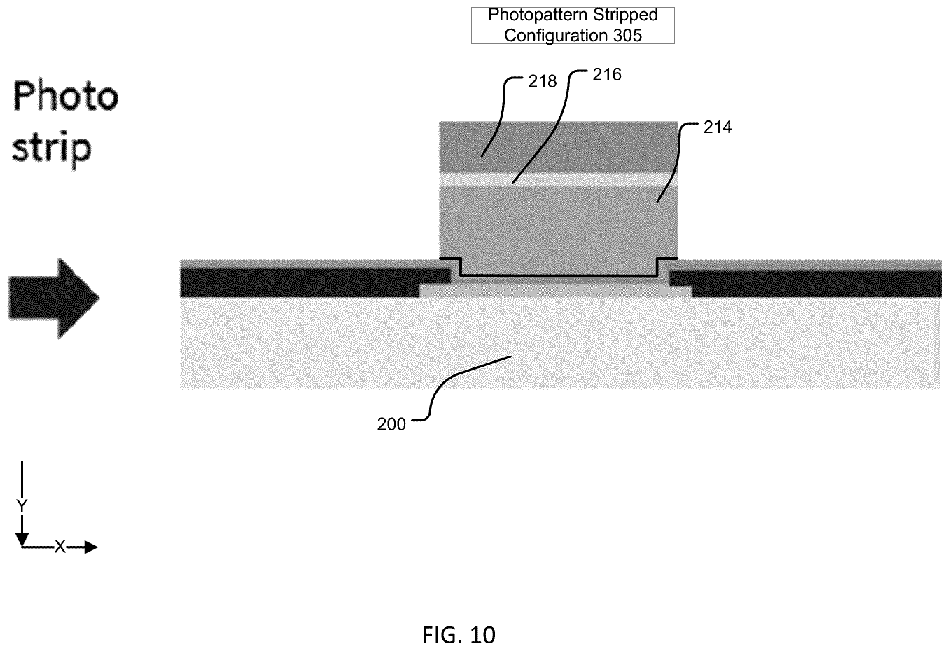

FIG. 10 illustrates a photopattern stripped configuration of the at least one integrated passive device according to FIG. 5.

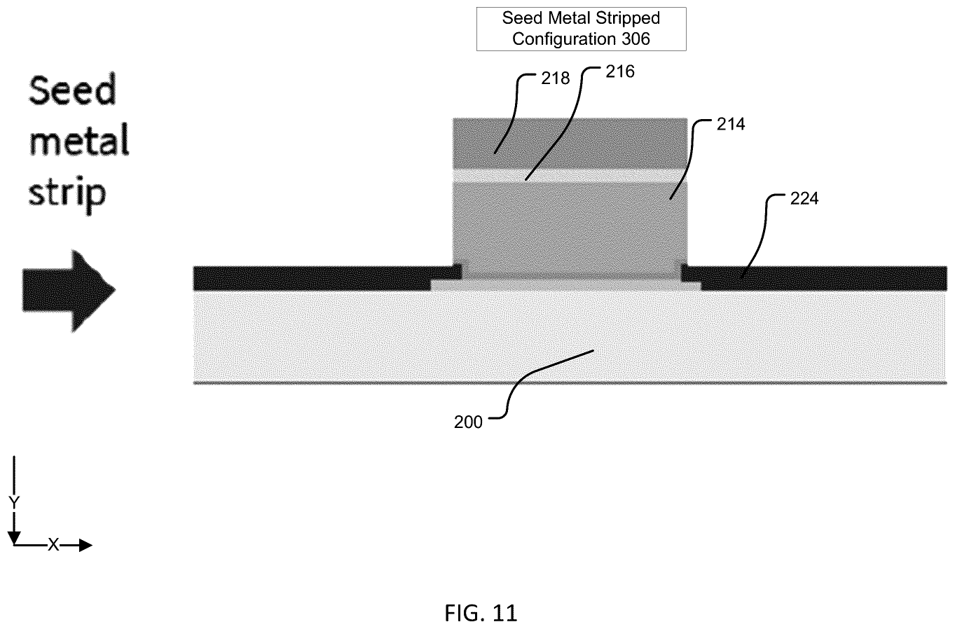

FIG. 11 illustrates a seed metal stripped configuration of the at least one integrated passive device according to FIG. 5.

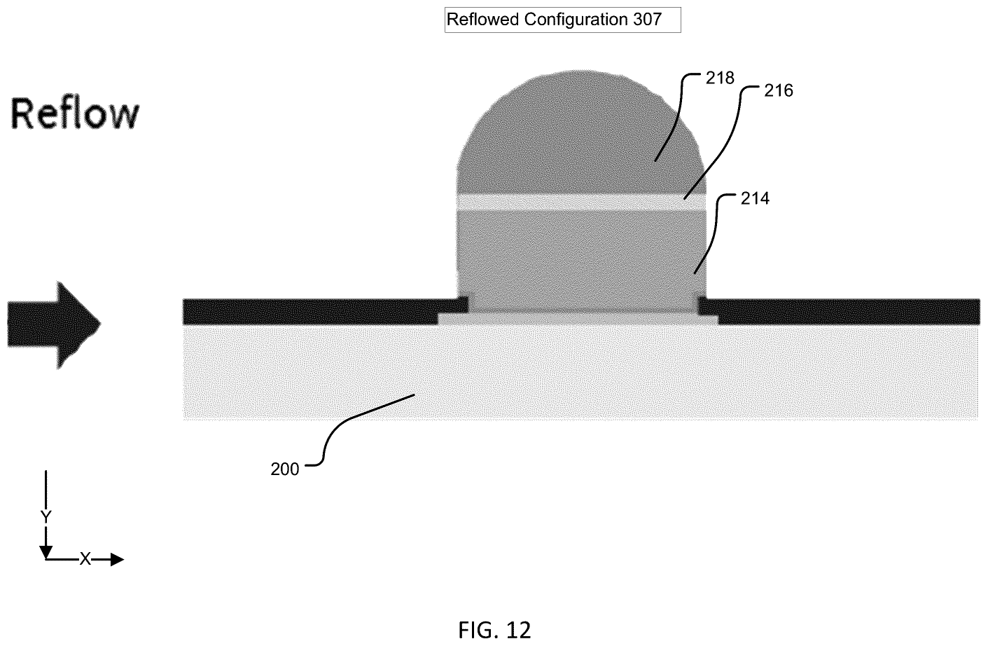

FIG. 12 illustrates a reflowed configuration of the at least one integrated passive device according to FIG. 5.

In particular, FIG. 5 illustrates an exemplary process flow 300 for forming the at least one bond pad 202 and the at least one connection structure 204 of the at least one integrated passive device 200 according to aspects of the disclosure. More specifically, FIG. 5 illustrates an initial configuration 301, a seed metal deposition configuration 302, a photopatterned configuration 303, a plated configuration 304, a photopattern stripped configuration 305, a seed metal stripped configuration 306, and a reflowed configuration 307.

In this regard, FIG. 6 illustrates the initial configuration 301 of the at least one integrated passive device 200 according to FIG. 5. More specifically, the initial configuration 301 may be such that the at least one integrated passive device 200 includes the metallization layer 220 and the passivation layer 224.

Further, FIG. 7 illustrates the seed metal deposition configuration 302 of the at least one integrated passive device 200 according to FIG. 5. More specifically, the seed metal deposition configuration 302 may be such that the at least one integrated passive device 200 includes the first layer 211 and the second layer 212 configured, arranged, and/or implemented as described herein.

Additionally, FIG. 8 illustrates the photopatterned configuration 303 of the at least one integrated passive device 200 according to FIG. 5. More specifically, the photopatterned configuration 303 may be such that the at least one integrated passive device 200 now includes a photopattern resist 290 on the at least one integrated passive device 200.

Further, FIG. 9 illustrates the plated configuration 304 of the at least one integrated passive device 200 according to FIG. 5. More specifically, the plated configuration 304 may be such that the pillar portion 214, the layer portion 216, and the solder portion 218 may be arranged on the at least one integrated passive device 200 configured, arranged, and/or implemented as described herein.

Additionally, FIG. 10 illustrates the photopattern stripped configuration 305 of the at least one integrated passive device 200 according to FIG. 5. More specifically, the photopattern stripped configuration 305 may be such that the photopattern resist 290 has been removed from the at least one integrated passive device 200.

Further, FIG. 11 illustrates the seed metal stripped configuration 306 of the at least one integrated passive device 200 according to FIG. 5. More specifically, the seed metal stripped configuration 306 may be such that portions of the first layer 211 and the second layer 212 have been removed from exposed surfaces of the passivation layer 224.

Additionally, FIG. 12 illustrates the reflowed configuration 307 of the at least one integrated passive device 200 according to FIG. 5. More specifically, the reflowed configuration 307 may be such that the solder portion 218 has been reflowed to form a dome like shape on the at least one integrated passive device 200.

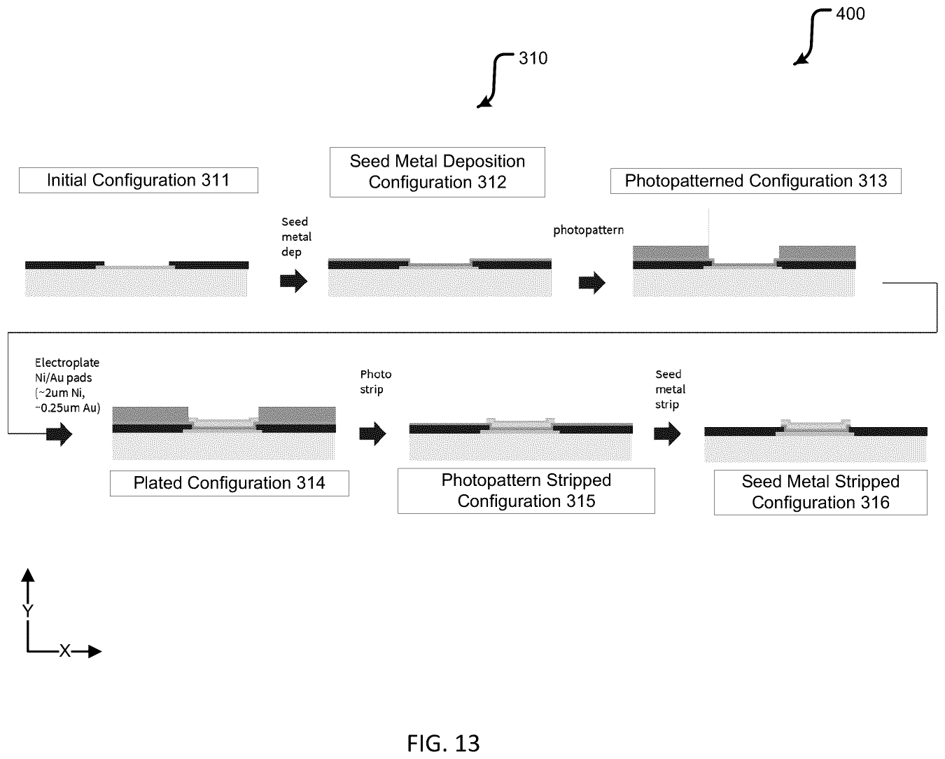

FIG. 13 illustrates an exemplary process flow for forming the at least one bond pad of the at least one semiconductor device according to aspects of the disclosure.

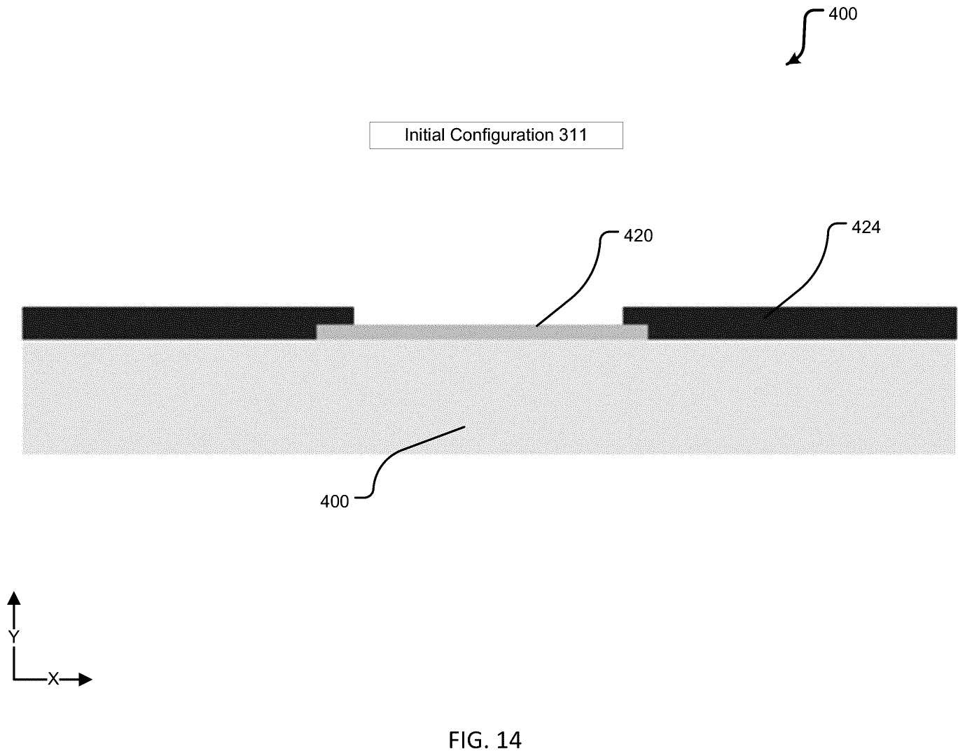

FIG. 14 illustrates an initial configuration of the at least one semiconductor device according to FIG. 13.

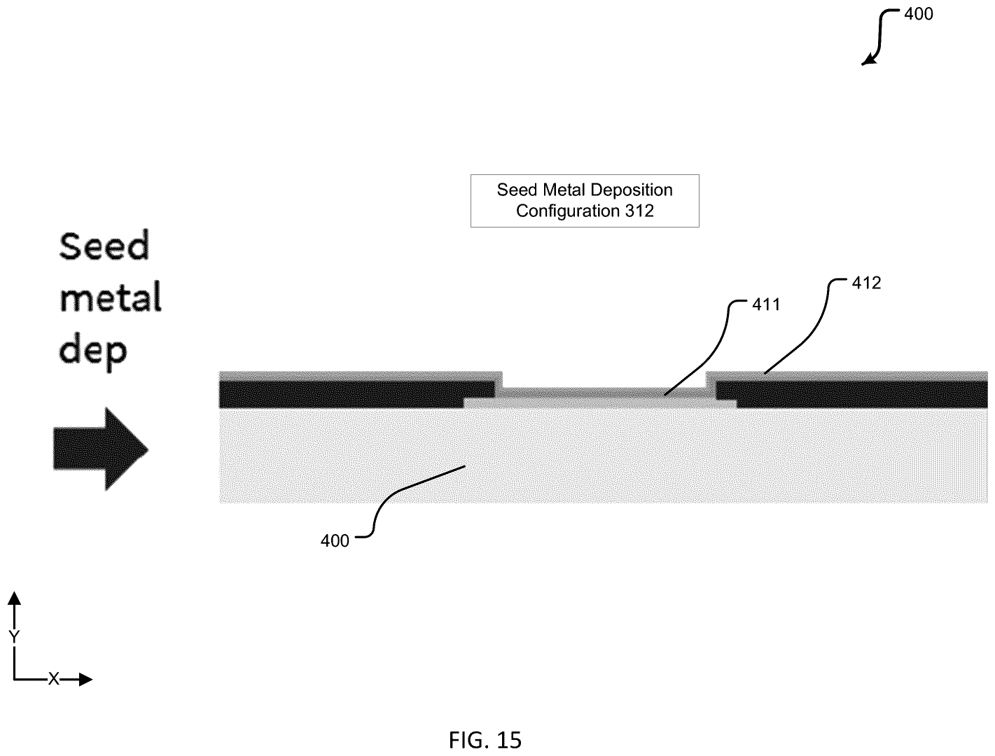

FIG. 15 illustrates a seed metal deposition configuration of the at least one semiconductor device according to FIG. 13.

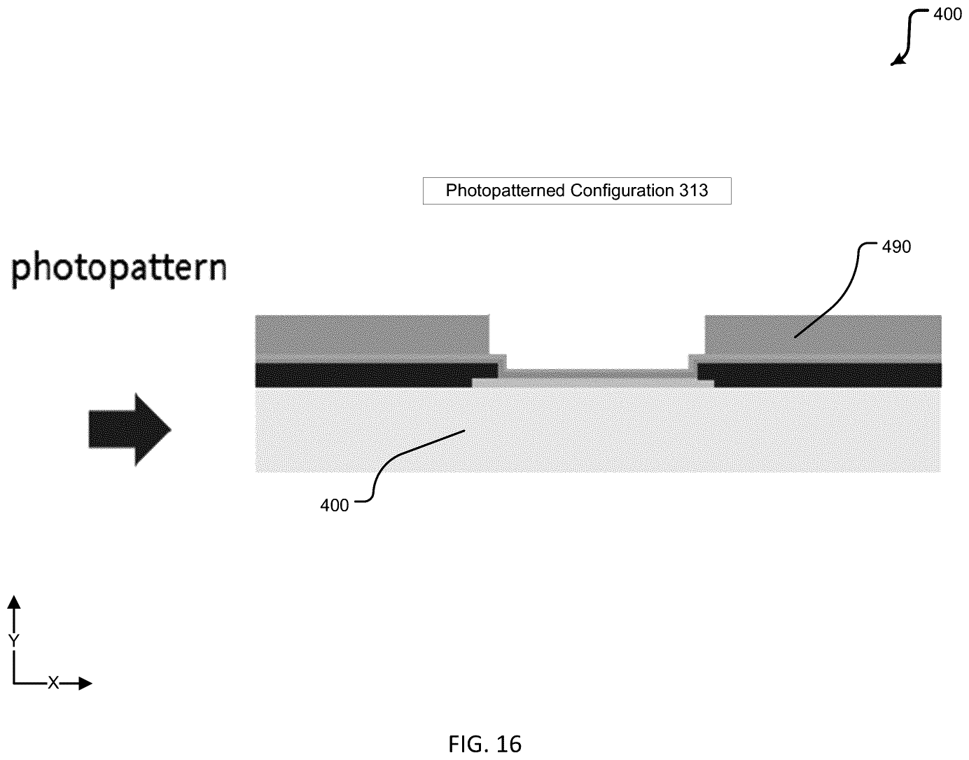

FIG. 16 illustrates a photopatterned configuration of the at least one semiconductor device according to FIG. 13.

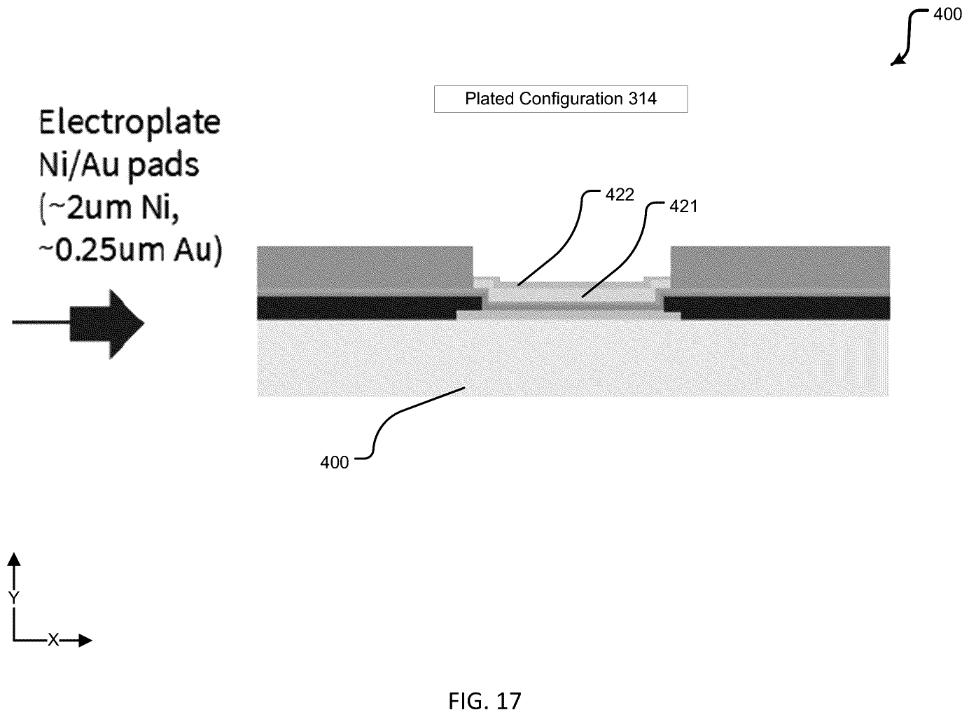

FIG. 17 illustrates a plated configuration of the at least one semiconductor device according to FIG. 13.

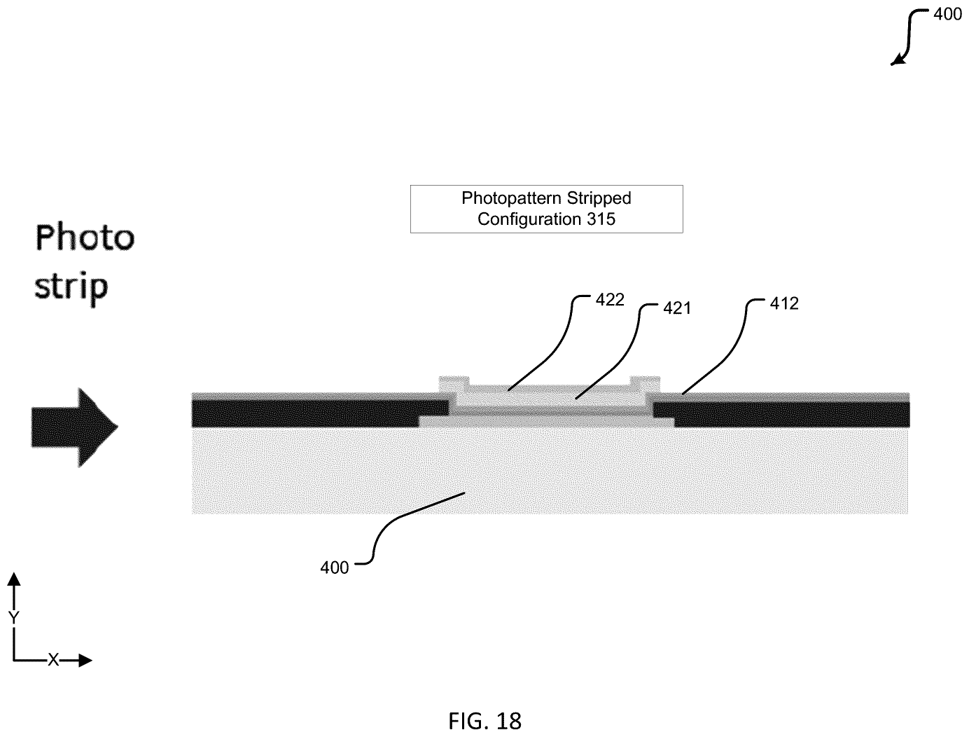

FIG. 18 illustrates a photopattern stripped configuration of the at least one semiconductor device according to FIG. 13.

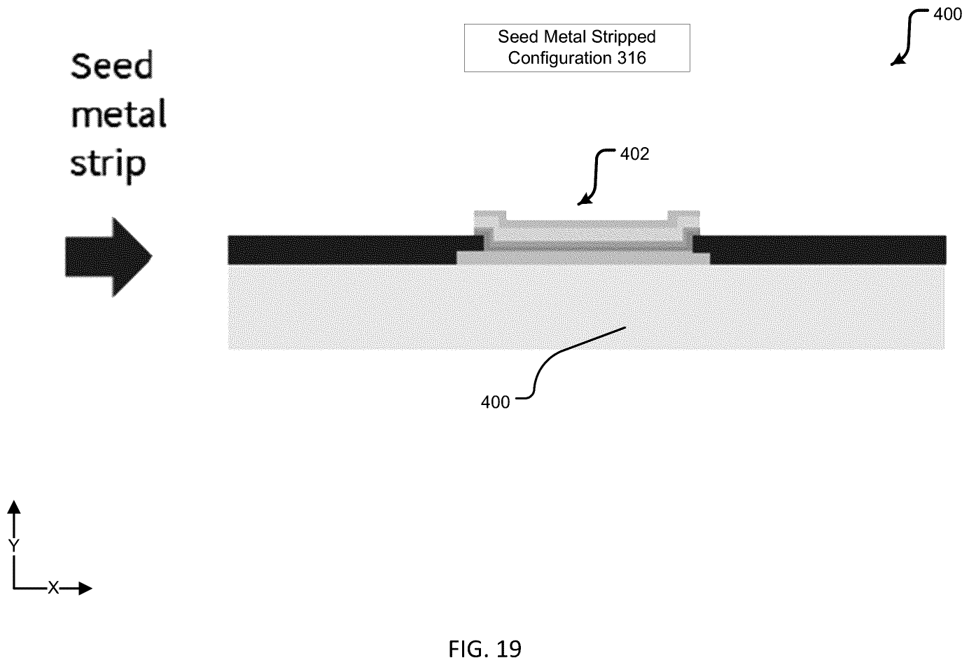

FIG. 19 illustrates a seed metal stripped configuration of the at least one semiconductor device according to FIG. 13.

In particular, FIG. 13 illustrates an exemplary process flow 310 for forming the at least one bond pad 402 of the at least one semiconductor device 400 according to aspects of the disclosure. More specifically, FIG. 13 illustrates an initial configuration 311, a seed metal deposition configuration 312, a photopatterned configuration 313, a plated configuration 314, a photopattern stripped configuration 315, and a seed metal stripped configuration 316.

Further, FIG. 14 illustrates an initial configuration 311 of the at least one semiconductor device 400 according to FIG. 13. More specifically, FIG. 14 illustrates the at least one semiconductor device 400 with the metallization layer 420 and the passivation layer 424.

Additionally, FIG. 15 illustrates the seed metal deposition configuration 312 of the at least one semiconductor device 400 according to FIG. 13. More specifically, FIG. 15 illustrates the at least one semiconductor device 400 with the first layer 411 and the second layer 412 configured, arranged, and/or implemented as described herein.

Further, FIG. 16 illustrates the photopatterned configuration 313 of the at least one semiconductor device 400 according to FIG. 13. More specifically, FIG. 16 illustrates the at least one semiconductor device 400 with a photoresist 490.

Additionally, FIG. 17 illustrates the plated configuration 314 of the at least one semiconductor device 400 according to FIG. 13. More specifically, FIG. 17 illustrates plating of the first pad structure 421 and the second pad structure 422 on the at least one semiconductor device 400 configured, arranged, and/or implemented as described herein.

Further, FIG. 18 illustrates the photopattern stripped configuration 315 of the at least one semiconductor device 400 according to FIG. 13. More specifically, FIG. 18 illustrates that the photoresist 490 has been stripped from the second layer 412 of the at least one semiconductor device 400.

Further, FIG. 19 illustrates the seed metal stripped configuration 316 of the at least one semiconductor device 400 according to FIG. 13. More specifically, FIG. 19 illustrates that the first pad structure 421 and the second pad structure 422 has been stripped from the passivation layer 424 of the at least one semiconductor device 400.

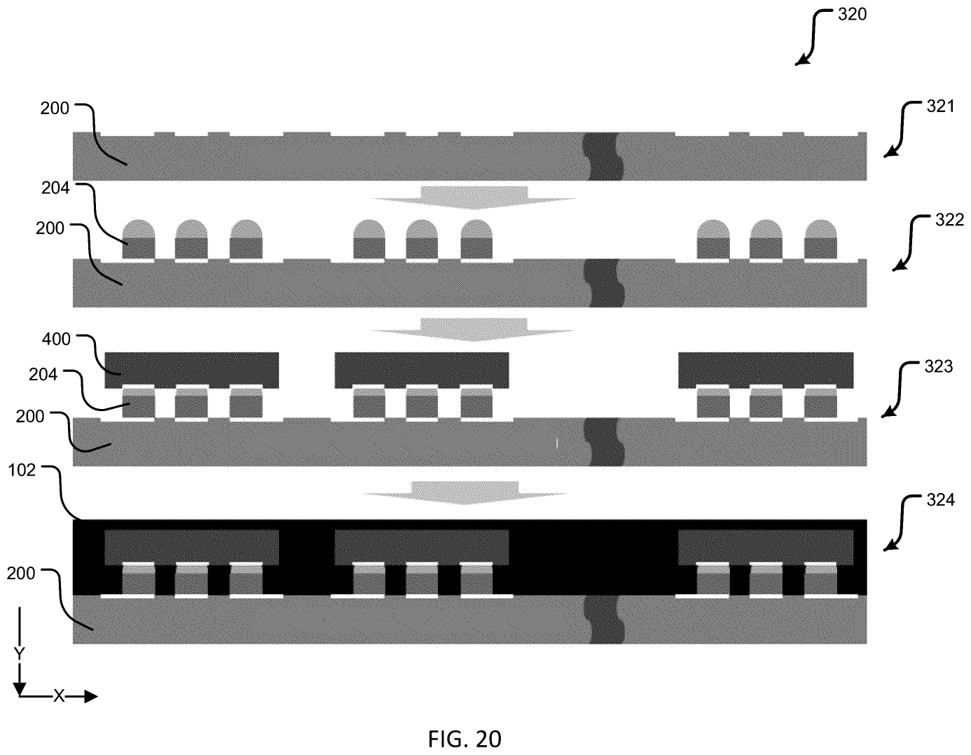

FIG. 20 illustrates exemplary wafer level processing of a wafer of the at least one integrated passive device according to aspects of the disclosure.

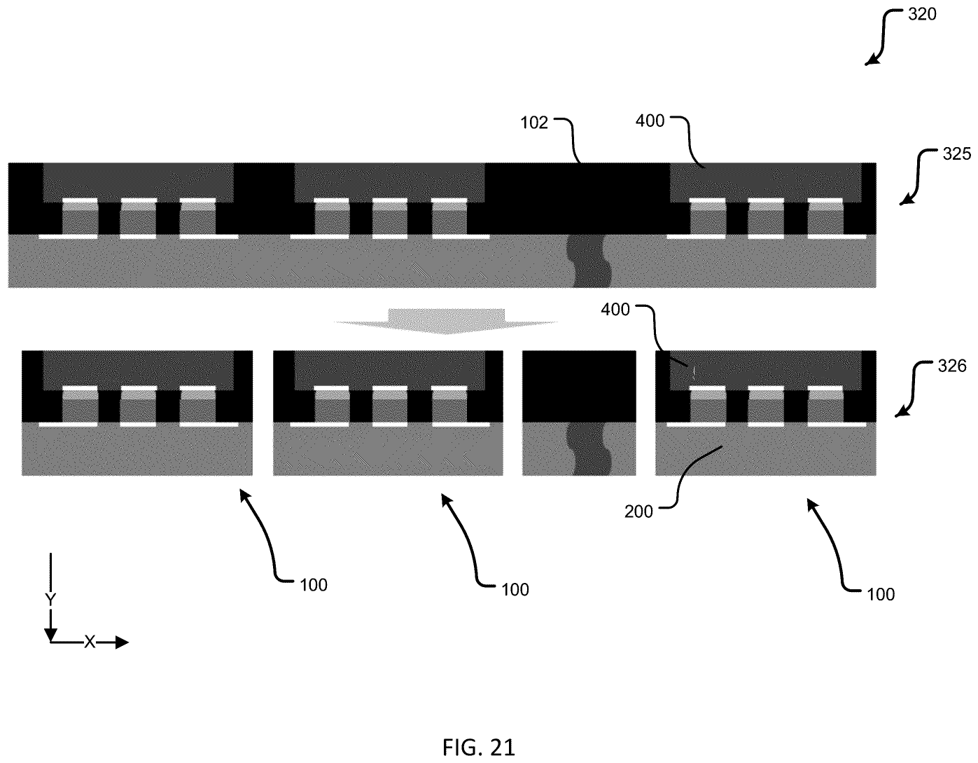

FIG. 21 further illustrates the exemplary wafer level processing of a wafer of the at least one integrated passive device according to aspects of the disclosure.

In particular, FIG. 20 illustrates exemplary wafer level processing of a wafer of the at least one integrated passive device 320 according to aspects of the disclosure. FIG. 20 further illustrates an initial wafer of the at least one integrated passive device 321 that relates to a wafer of the at least one integrated passive device 200 as described herein.

FIG. 20 further illustrates a bumping of the wafer of the at least one integrated passive device process 322 that includes formation of the at least one connection structure 204 on the at least one integrated passive device 200 as described herein. Further, FIG. 20 illustrates attachment of the at least one semiconductor device attachment to the wafer of the at least one integrated passive device process 323. In particular, attachment of the at least one semiconductor device 400 to the at least one connection structure 204 of the at least one integrated passive device 200. In aspects, the at least one semiconductor device attachment to the wafer of the at least one integrated passive device process 323 may include alignment of the at least one semiconductor device 400 with respect to the at least one integrated passive device 200.

Further, FIG. 20 illustrates a molding of the wafer of the at least one integrated passive device process 324. In particular, arranging the packaging compound 102 between the at least one semiconductor device 400 and the at least one integrated passive device 200 configured, arranged, and/or implemented as described herein. In aspects, the packaging compound 102 may extend over and around the at least one semiconductor device 400 and across the at least one integrated passive device 200. Thereafter, the assembly of the at least one integrated passive device 200 and the at least one semiconductor device 400 may be flipped and further configured as needed for implementation as the packaged device 100.

With reference to FIG. 21, the exemplary wafer level processing of a wafer of the at least one integrated passive device 320 may further include a grinding of the wafer of the at least one integrated passive device process 325. In particular, grinding the packaging compound 102 to expose a surface of the at least one semiconductor device 400.

Further, FIG. 21 illustrates a singluation of wafer of the at least one integrated passive device process 326. In particular, separate implementations of the at least one integrated passive device 200 may be singulated from the wafer that held multiple implementations of the at least one integrated passive device 200. In aspects, the singluation of wafer of the at least one integrated passive device process 326 of the at least one semiconductor device 400 on the at least one integrated passive device 200 may be implemented in one shot. In other words, simultaneously. In this regard, the singluation of wafer of the at least one integrated passive device process 326 may result in a unit cell having a single implementation of the at least one semiconductor device 400 on the at least one integrated passive device 200 and/or a unit cell having a multiple implementations of the at least one semiconductor device 400 on the at least one integrated passive device 200.

In some aspects, the singluation of wafer of the at least one integrated passive device process 326 may include cutting the wafer utilizing cutting equipment such as wafer, circuit board, or package sawing equipment to singulate the at least one integrated passive device 200 from the wafer.

In one exemplary method, the at least one semiconductor device 400 can be molded to the wafer accommodating a plurality of implementations of the at least one integrated passive device 200 using vacuum assisted molding. This may create a blanket, void-free encapsulation of the at least one semiconductor device 400 attached to the IPD wafer accommodating a plurality of implementations of the at least one integrated passive device 200. For this method, the IPD wafer dicing may include dicing through the wafer level molding to obtain individual implementations of the at least one integrated passive device 200 having the at least one semiconductor device 400 thereon.

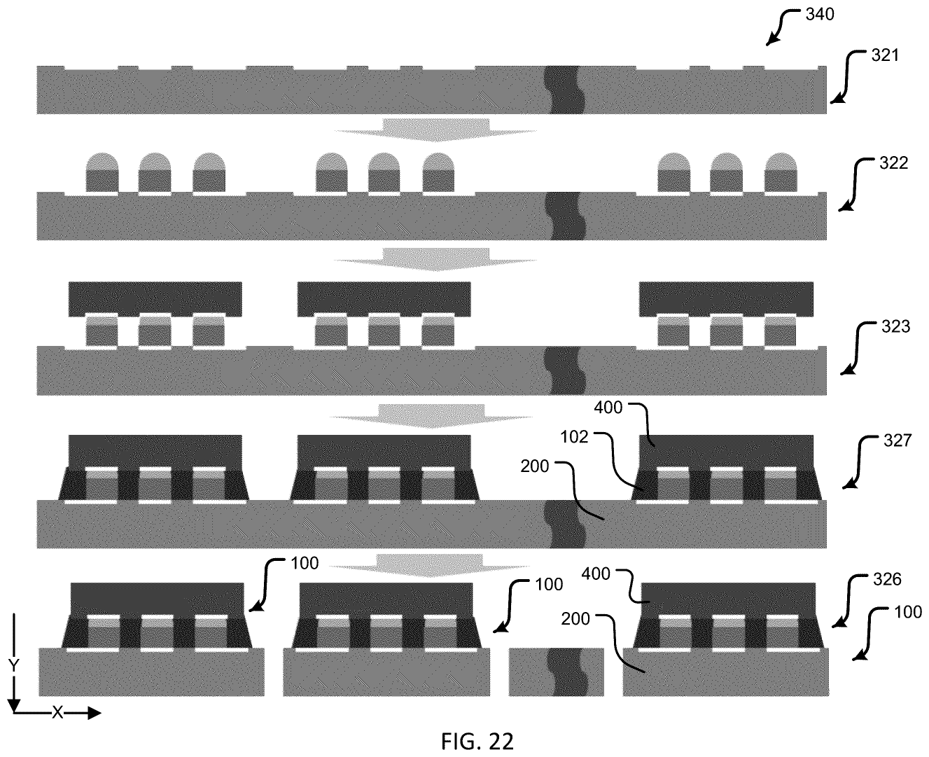

FIG. 22 illustrates another exemplary wafer level processing of a wafer of the at least one integrated passive device.

In particular, FIG. 22 illustrates another exemplary wafer level processing of a wafer of the at least one integrated passive device 340. In this regard, the another exemplary wafer level processing of a wafer of the at least one integrated passive device 340 may include the initial wafer of the at least one integrated passive device 321, the bumping of the wafer of the at least one integrated passive device process 322, the at least one semiconductor device attachment to the wafer of the at least one integrated passive device process 323, and the singluation of wafer of the at least one integrated passive device process 326 as previously described with reference to the exemplary wafer level processing of a wafer of the at least one integrated passive device 320. Additionally, the another exemplary wafer level processing of a wafer of the at least one integrated passive device 340 may include implementing an underfill of the wafer of the at least one integrated passive device 327. In particular, the packaging compound 102 may be underfilled between the at least one semiconductor device 400 and the at least one integrated passive device 200. Thereafter, the assembly of the at least one integrated passive device 200 and the at least one semiconductor device 400 may be flipped and further configured as needed for implementation as the packaged device 100.

In further aspects, the at least one integrated passive device 200 may be implemented as a printed circuit board (PCB), a printed wiring board (PWB), a printed circuit board assembly (PCBA), a medium used to connect electronic components to one another in a controlled manner, and/or the like hereinafter a PCB for brevity. In aspects, the PCB implementation of the at least one integrated passive device 200 may optionally include any one or more features, structures, components, and/or the like of the at least one integrated passive device 200 as described herein. In particular, the at least one connection structure 204 may be formed on the PCB implementation of the at least one integrated passive device 200 and subsequently the at least one semiconductor device 400 may be attached the at least one connection structure 204 of the PCB implementation of the at least one integrated passive device 200. Further, the packaged device 100 implementing the PCB implementation of the at least one integrated passive device 200 may include any other constructions and configurations as described herein.

Further, the PCB implementation of the at least one integrated passive device 200 may include additional and/or alternative fabrication processes including stencil printing, mask application and removal, solder reflow, coining to form coined implementations of the solder portion 218, and/or the like.

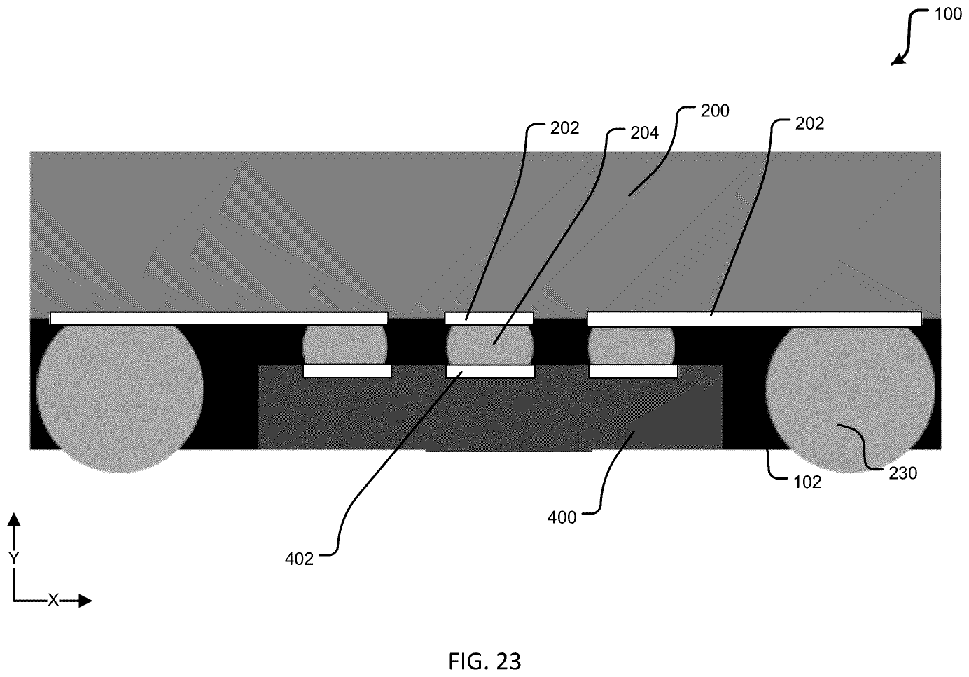

FIG. 23 illustrates a cross-sectional view of another implementation of the packaged device according to aspects of the disclosure.

In particular, FIG. 23 illustrates a cross-sectional view of another implementation of the packaged device 100 according to aspects of the disclosure. In this regard, the packaged device 100 illustrated in FIG. 23 may optionally include any one or more the aspects of the packaged device 100 as described herein and illustrated with respect to the other Figures of the disclosure. Moreover, the other aspects as described herein may optionally include any of the aspects illustrated in FIG. 23 and described with respect to FIG. 23.

In particular, FIG. 23 illustrates an implementation of the packaged device 100 where the packaging compound 102 further encapsulates portions of one or more implementations of the at least one solder ball connection 230. Additionally, the packaging compound 102 may encapsulate at least portions of the vertical sides of the at least one semiconductor device 400. Moreover, the packaging compound 102 may fully encapsulate all implementations of the at least one bond pad 202. In aspects, the at least one solder ball connection 230 may be implemented as a ball drop configuration, a through mold via, and/or the like. Further, the at least one solder ball connection 230 may be formed before or after singulation of the at least one integrated passive device 200 and the at least one semiconductor device 400.

In particular aspects, the at least one semiconductor device 400 can be individually underfilled using capillary underfill, relying on natural capillary vacuum to draw the underfill epoxy only through a bond line of the die. In this aspect, dicing streets of the IPD wafer accommodating a plurality of implementations of the at least one integrated passive device 200 may be left clear for standard SiC dicing.

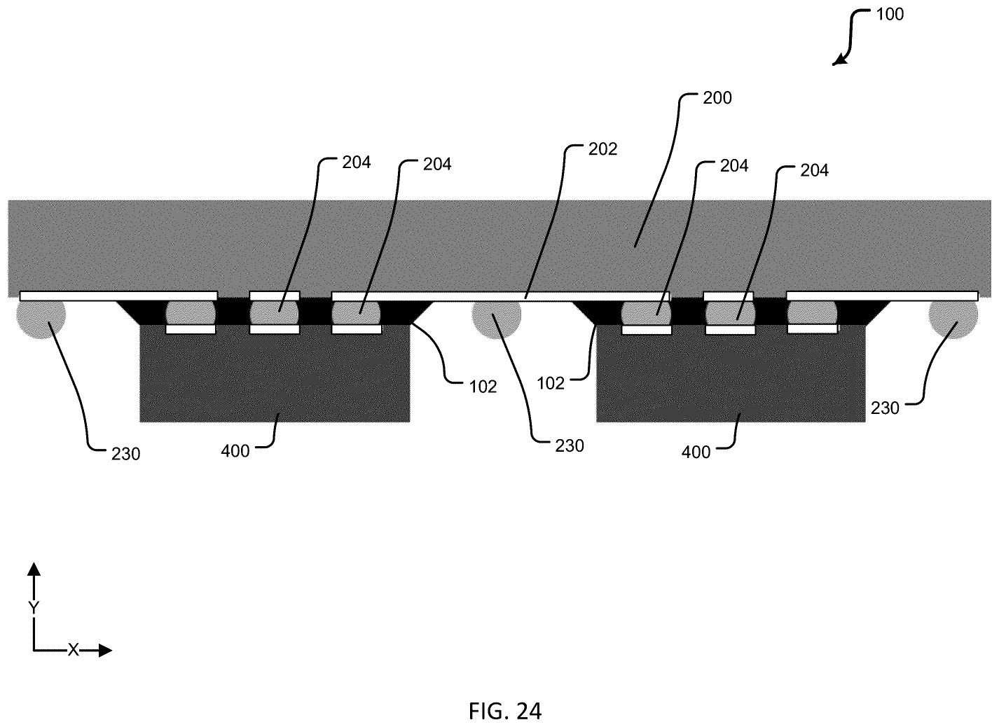

FIG. 24 illustrates a cross-sectional view of another implementation of the packaged device according to aspects of the disclosure.

In particular, FIG. 24 illustrates a cross-sectional view of another implementation of the packaged device 100 according to aspects of the disclosure. In this regard, the packaged device 100 illustrated in FIG. 24 may optionally include any one or more the aspects of the packaged device 100 as described herein and illustrated with respect to the other Figures of the disclosure. Moreover, the other aspects as described herein may optionally include any of the aspects illustrated in FIG. 24 and described with respect to FIG. 24.

In particular, FIG. 24 illustrates an implementation of the packaged device 100 having multiple implementations of the at least one semiconductor device 400. Additionally, the implementation of the at least one integrated passive device 200 may include an elongated implementation of the at least one bond pad 202 that extends from one implementation of the at least one connection structure 204 connected to one implementation of the at least one semiconductor device 400; and the elongated implementation of the at least one bond pad 202 further extends from another implementation of the at least one connection structure 204 connected to another implementation of the at least one semiconductor device 400.

Additionally, FIG. 24 illustrates that each implementation of the at least one semiconductor device 400 may be configured with a separate implementation of the packaging compound 102 arranged as an underfill between each implementation of the at least one semiconductor device 400 and the at least one integrated passive device 200.

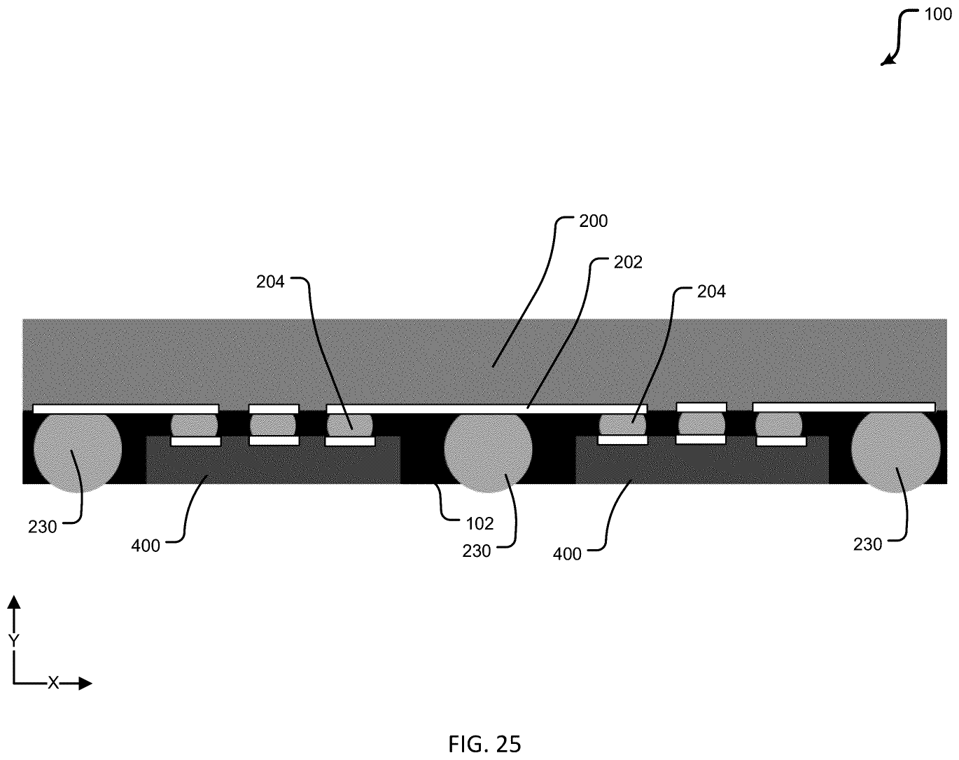

FIG. 25 illustrates a cross-sectional view of another implementation of the packaged device according to aspects of the disclosure.

In particular, FIG. 25 illustrates a cross-sectional view of another implementation of the packaged device 100 according to aspects of the disclosure. In this regard, the packaged device 100 illustrated in FIG. 25 may optionally include any one or more the aspects of the packaged device 100 as described herein and illustrated with respect to the other Figures of the disclosure. Moreover, the other aspects as described herein may optionally include any of the aspects illustrated in FIG. 25 and described with respect to FIG. 25.

In particular, FIG. 25 illustrates an implementation of the packaged device 100 having multiple implementations of the at least one semiconductor device 400. Additionally, the implementation of the at least one integrated passive device 200 may include an elongated implementation of the at least one bond pad 202 that extends from one implementation of the at least one connection structure 204 connected to one implementation of the at least one semiconductor device 400; and the elongated implementation of the at least one bond pad 202 further extends to another implementation of the at least one connection structure 204 connected to another implementation of the at least one semiconductor device 400. Additionally, the elongated implementation of the at least one integrated passive device 200 to may further include implementation of the at least one solder ball connection 230.

As further illustrated in FIG. 25, the packaging compound 102 may encapsulate one or more implementations of the at least one connection structure 204. In aspects, the packaging compound 102 may encapsulate all implementations of the at least one connection structure 204.

Further, the packaging compound 102 may at least partially encapsulate one or more implementations of the at least one solder ball connection 230. In aspects, the packaging compound 102 may partially encapsulate all implementations of the at least one solder ball connection 230.

Additionally, the packaging compound 102 may encapsulate the vertical sides of one or more implementations of the at least one semiconductor device 400. In aspects, the packaging compound 102 may encapsulate the vertical sides of all implementations of the at least one semiconductor device 400.

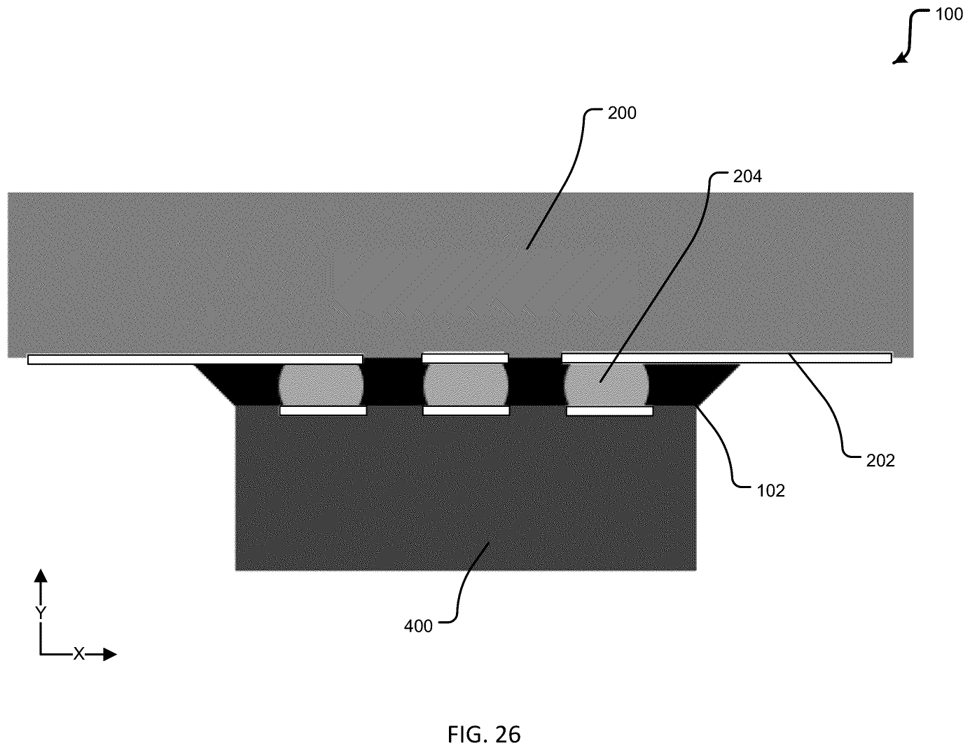

FIG. 26 illustrates a cross-sectional view of another implementation of the packaged device according to aspects of the disclosure.

In particular, FIG. 26 illustrates a cross-sectional view of another implementation of the packaged device 100 according to aspects of the disclosure. In this regard, the packaged device 100 illustrated in FIG. 26 may optionally include any one or more the aspects of the packaged device 100 as described herein and illustrated with respect to the other Figures of the disclosure. Moreover, the other aspects as described herein may optionally include any of the aspects illustrated in FIG. 26 and described with respect to FIG. 26.

In particular, FIG. 26 illustrates an implementation of the packaged device 100 that includes one or more elongated implementations of the at least one bond pad 202. In this regard, the packaging compound 102 may encapsulate one or more implementations of the at least one connection structure 204. Further, the packaging compound 102 may be implemented as an underfill between the at least one semiconductor device 400 and the at least one integrated passive device 200.

In additional aspects, the packaging compound 102 may not encapsulate portions of the at least one bond pad 202. In particular, portions of the elongated implementations of the at least one bond pad 202 may extend from the packaging compound 102 for electrical connection to other components.

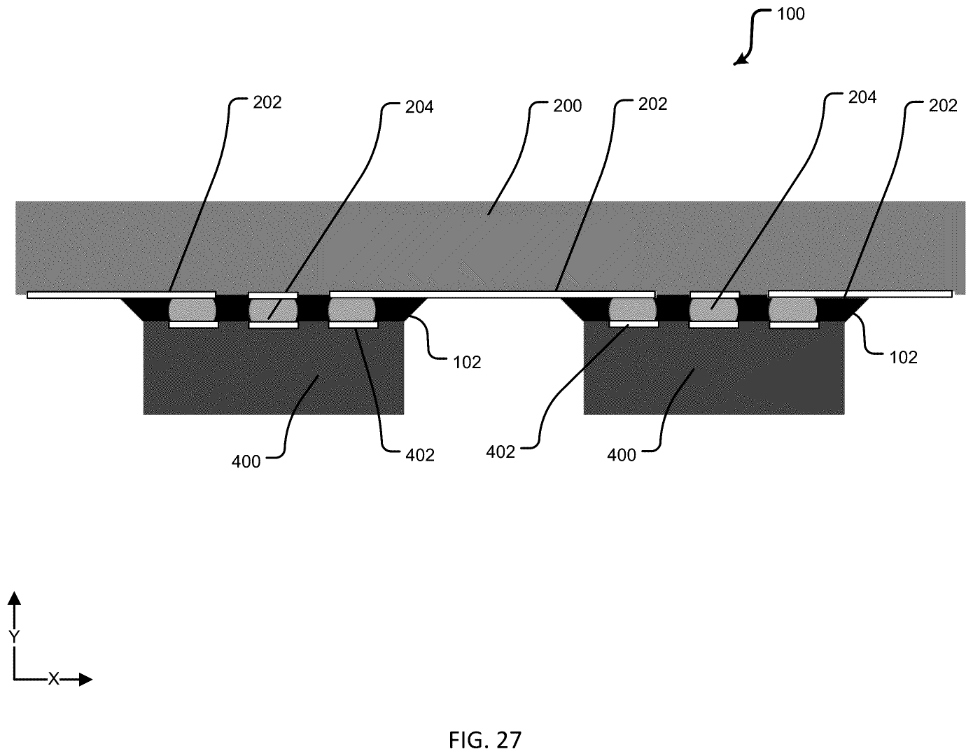

FIG. 27 illustrates a cross-sectional view of another implementation of the packaged device according to aspects of the disclosure.

In particular, FIG. 27 illustrates a cross-sectional view of another implementation of the packaged device 100 according to aspects of the disclosure. In this regard, the packaged device 100 illustrated in FIG. 27 may optionally include any one or more the aspects of the packaged device 100 as described herein and illustrated with respect to the other Figures of the disclosure. Moreover, the other aspects as described herein may optionally include any of the aspects illustrated in FIG. 27 and described with respect to FIG. 27.

In particular, FIG. 27 illustrates an implementation of the packaged device 100 that includes one or more elongated implementations of the at least one bond pad 202. In this regard, the packaging compound 102 may encapsulate one or more implementations of the at least one connection structure 204. Further, the packaging compound 102 may be implemented as an underfill between the at least one semiconductor device 400 and the at least one integrated passive device 200.

In additional aspects, the packaging compound 102 may not encapsulate portions of the at least one bond pad 202. In particular, portions of the elongated implementations of the at least one bond pad 202 may extend from the packaging compound 102 for electrical connection to other components.

In particular, FIG. 27 illustrates an implementation of the packaged device 100 having multiple implementations of the at least one semiconductor device 400. Additionally, the implementation of the at least one integrated passive device 200 may include an elongated implementation of the at least one bond pad 202 that extends from one implementation of the at least one connection structure 204 connected to one implementation of the at least one semiconductor device 400; and the elongated implementation of the at least one bond pad 202 further extends to another implementation of the at least one connection structure 204 connected to another implementation of the at least one semiconductor device 400. Additionally, the packaged device 100 illustrated in FIG. 27 does not include any implementations of the at least one solder ball connection 230.

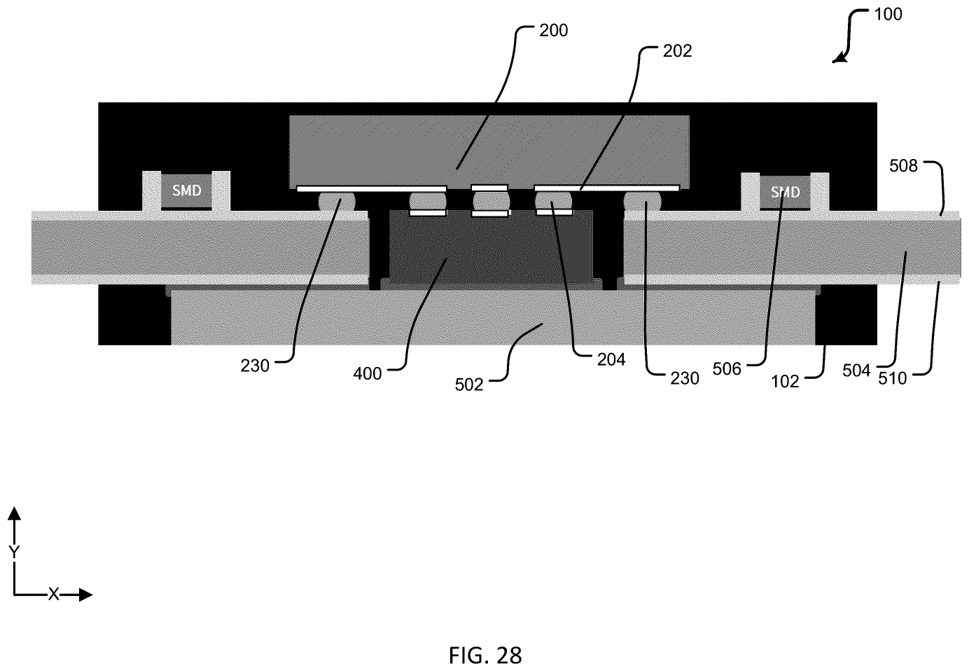

FIG. 28 illustrates a cross-sectional view of another implementation of the packaged device according to aspects of the disclosure.

In particular, FIG. 28 illustrates a cross-sectional view of another implementation of the packaged device 100 according to aspects of the disclosure. In this regard, the packaged device 100 illustrated in FIG. 28 may optionally include any one or more the aspects of the packaged device 100 as described herein and illustrated with respect to the other Figures of the disclosure. Moreover, the other aspects as described herein may optionally include any of the aspects illustrated in FIG. 28 and described with respect to FIG. 28.

In aspects, the packaged device 100 that may include, may be attached to, may be configured to be attached to, and/or the like a heat sink 502. In aspects, the at least one semiconductor device 400 may be attached to the heat sink 502 by solder, adhesive, sintering, eutectic bonding, ultrasonic welding, and/or the like. In aspects, heat generated from the at least one semiconductor device 400 may be transferred to the heat sink 502.

The heat sink 502 may be implemented as a metal submount and may be implemented as a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The heat sink 502 may include an insulating material, a dielectric material, and/or the like.

In aspects, the packaged device 100 that may include, may be attached to, may be configured to be attached to, and/or the like at least one component 504. The at least one component 504 may be a printed circuit board (PCB) and/or the like. The at least one component 504 may include a lower surface metallization 510 and an upper surface metallization 508.

In aspects, the at least one component 504 may include at least one surface mount device (SMD) 506. In aspects, the at least one surface mount device (SMD) 506 may be attached directly or indirectly to the upper surface metallization 508 of the at least one component 504. In aspects, the at least one integrated passive device 200 may include an elongated implementation of the at least one bond pad 202 that may be connected to the at least one solder ball connection 230. In aspects, the at least one solder ball connection 230 may be connected to the upper surface metallization 508 of the at least one component 504.

In aspects, the at least one component 504 may be connected to the heat sink 502. In aspects, the at least one component 504 may be connected to the heat sink 502 via the lower surface metallization 510. In aspects, the at least one component 504 may be attached to the heat sink 502 by solder, adhesive, sintering, eutectic bonding, ultrasonic welding, and/or the like. In aspects, heat generated from the at least one component 504 may be transferred to the heat sink 502.

In aspects, the at least one component 504 may be implemented as a printed circuit board (PCB), a printed wiring board (PWB), a printed circuit board assembly (PCBA), a medium used to connect electronic components to one another in a controlled manner, and/or the like. In aspects, the at least one component 504 may be implemented as a laminated sandwich structure of one or more conductive and insulating layers. In aspects, the at least one component 504 may include one or more conductive layers, traces, planes and/or the like. In aspects, the at least one component 504 may be etched from one or more sheet layers of copper laminated onto and/or between sheet layers of a non-conductive substrate. In aspects, the at least one component 504 may include plated-through holes that allow interconnections between layers.

In additional aspects, the at least one component 504 may include one or more circuits, reactive components, inductors, resistors, and/or the like. The at least one component 504 may be configured as or as part of an output impedance matching network, an input impedance matching network, a higher order harmonic termination circuit, a fundamental frequency matching circuit, and/or the like.

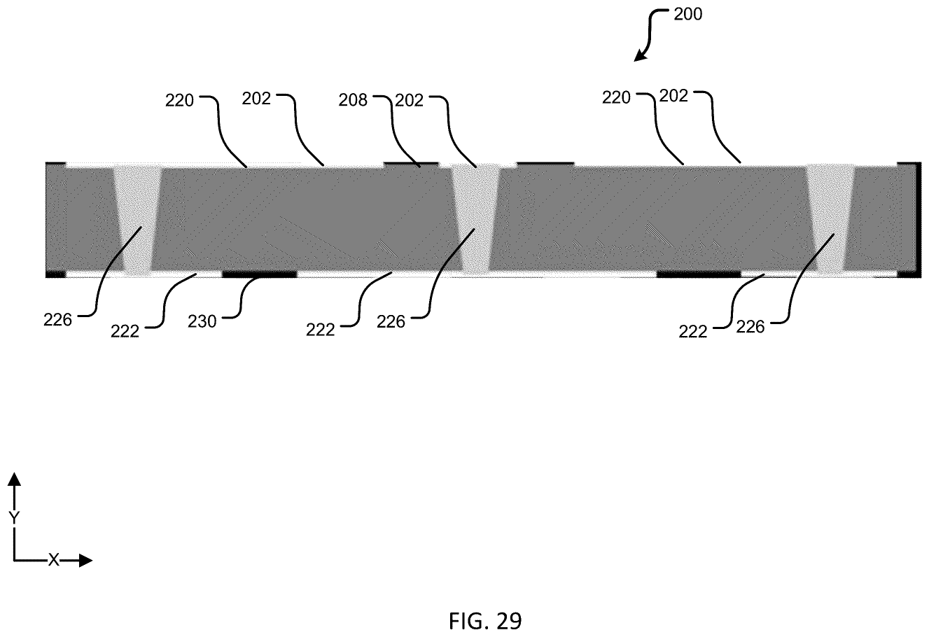

FIG. 29 illustrates a cross-sectional view of the at least one integrated passive device according to aspects of the disclosure.

In particular, FIG. 29 illustrates a cross-sectional view of the at least one integrated passive device 200 according to aspects of the disclosure. In this regard, the at least one integrated passive device 200 illustrated in FIG. 29 may optionally include any one or more the aspects of the at least one integrated passive device 200 as described herein and illustrated with respect to the other Figures of the disclosure. Moreover, the other aspects as described herein may optionally include any of the aspects of the at least one integrated passive device 200 illustrated in FIG. 29 and described with respect to FIG. 29.

Further, as illustrated in FIG. 29, the at least one integrated passive device 200 may include the at least one bond pad 202 and/or the metallization layer 220 arranged on the first surface 208 as previously described. Further, the at least one integrated passive device 200 may include a second metallization 222 arranged on the second surface 206. Moreover, the at least one integrated passive device 200 may include at least one via 226 arranged within the at least one integrated passive device 200. In aspects, the at least one via 226 may allow further three-dimensional stacking of components on the at least one integrated passive device 200. In aspects, the at least one via 226 may electrically connect the at least one bond pad 202 and/or the metallization layer 220 to the second metallization 222. Accordingly, aspects of the packaged device 100 implemented herein may implement the at least one integrated passive device 200 with a dual side pattern and/or feature on the at least one integrated passive device 200, which may be implemented by the at least one bond pad 202 and/or the metallization layer 220 and the second metallization 222.

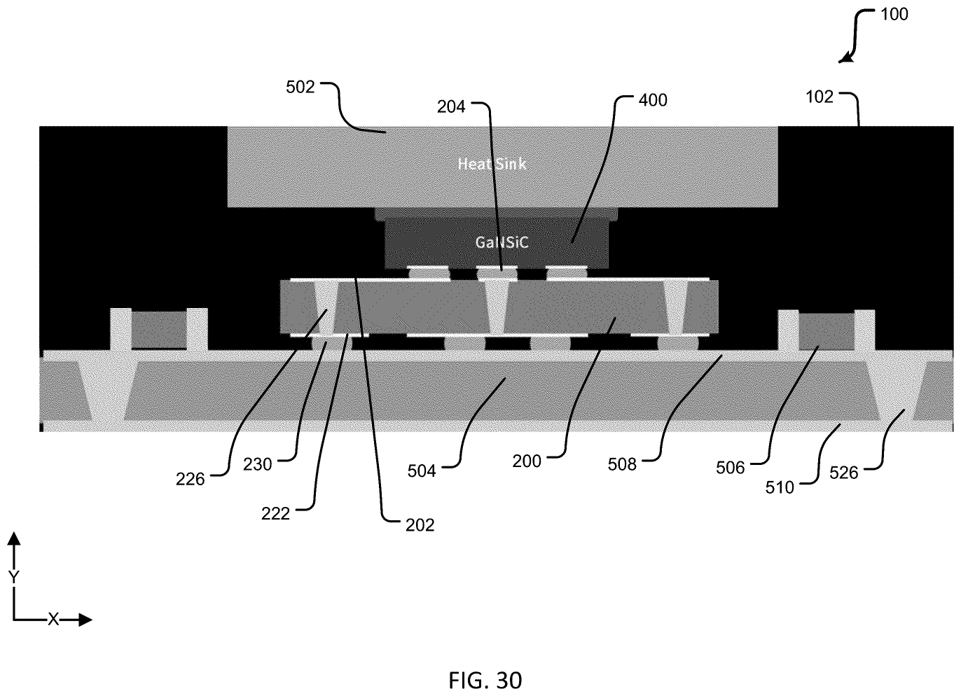

FIG. 30 illustrates a cross-sectional view of another implementation of the packaged device according to aspects of the disclosure.

In particular, FIG. 30 illustrates a cross-sectional view of another implementation of the packaged device 100 according to aspects of the disclosure. In this regard, the packaged device 100 illustrated in FIG. 30 may optionally include any one or more the aspects of the packaged device 100 as described herein and illustrated with respect to the other Figures of the disclosure. Moreover, the other aspects as described herein may optionally include any of the aspects illustrated in FIG. 30 and described with respect to FIG. 30.

As illustrated in FIG. 30, the packaged device 100 may be configured such that the at least one integrated passive device 200 may be attached to the at least one component 504 by the at least one solder ball connection 230. In particular, the at least one solder ball connection 230 may connect the second metallization 222 of the at least one integrated passive device 200 to the upper surface metallization 508 of the at least one component 504.

Further, the at least one semiconductor device 400 may be attached to the at least one connection structure 204 of the at least one integrated passive device 200 as previously described. Moreover, the at least one semiconductor device 400 may be attached to the heat sink 502. Accordingly, the implementation of the packaged device 100 illustrated in FIG. 30 may implement top side cooling by the arrangement of the heat sink 502 as illustrated. In aspects, the heat sink 502 may be attached to the at least one semiconductor device 400 after the at least one semiconductor device 400 is attached to the at least one integrated passive device 200

Further, the packaging compound 102 may surround and/or partially surround one or more of the at least one integrated passive device 200, the at least one semiconductor device 400, the heat sink 502, the at least one surface mount device (SMD) 506, the at least one solder ball connection 230, and the at least one component 504. Additionally, the at least one component 504 may implement at least one via 526. In aspects, the at least one via 526 may connect the upper surface metallization 508 of the at least one component 504 to the lower surface metallization 510 of the at least one component 504.

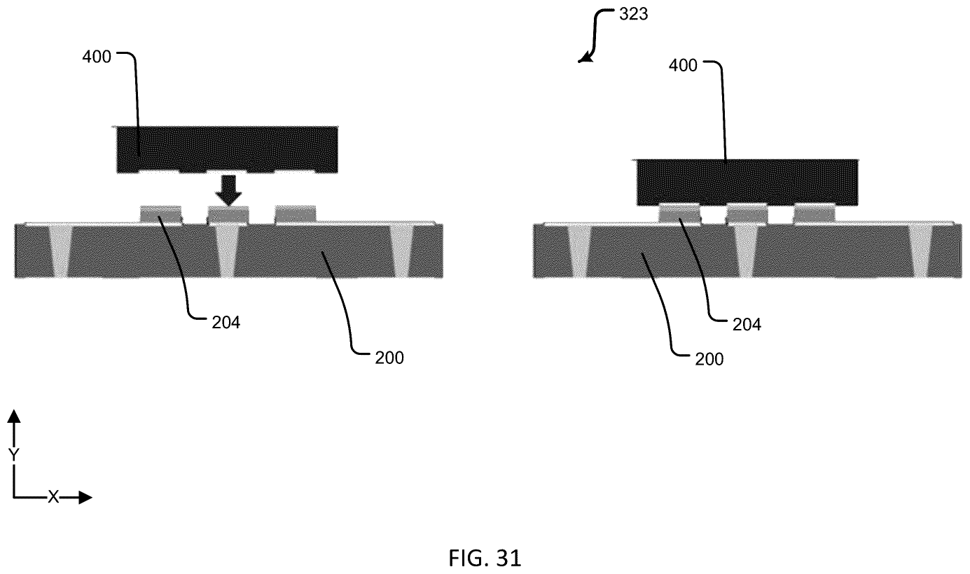

FIG. 31 illustrates exemplary wafer level processing of a wafer of the at least one integrated passive device according to aspects of the disclosure.

In particular, FIG. 31 illustrates exemplary wafer level processing of a wafer of the at least one integrated passive device according to aspects of the disclosure. In this regard, the packaged device 100 illustrated in FIG. 31 may optionally include any one or more the aspects of the packaged device 100 as described herein and illustrated with respect to the other Figures of the disclosure. Moreover, the other aspects as described herein may optionally include any of the aspects illustrated in FIG. 31 and described with respect to FIG. 31.

In particular, FIG. 31 illustrates the attachment of the at least one semiconductor device 400 to the at least one connection structure 204 arranged on the at least one integrated passive device 200. More specifically, FIG. 31 illustrates the at least one semiconductor device attachment to the wafer of the at least one integrated passive device process 323 as previously described herein.

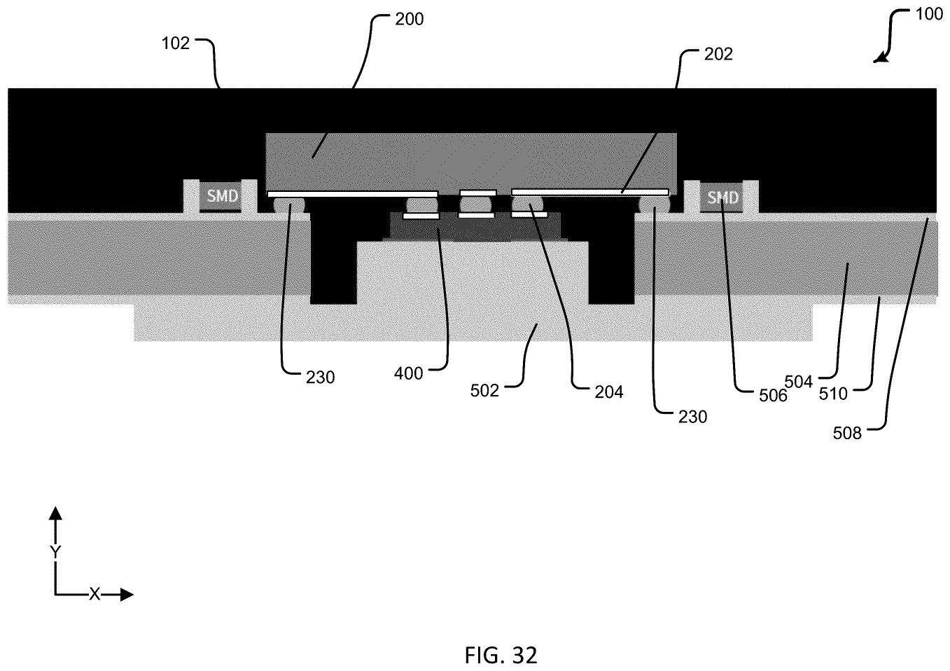

FIG. 32 illustrates a cross-sectional view of another implementation of the packaged device according to aspects of the disclosure.

In particular, FIG. 32 illustrates a cross-sectional view of another implementation of the packaged device 100 according to aspects of the disclosure. In this regard, the packaged device 100 illustrated in FIG. 32 may optionally include any one or more the aspects of the packaged device 100 as described herein and illustrated with respect to the other Figures of the disclosure. Moreover, the other aspects as described herein may optionally include any of the aspects illustrated in FIG. 32 and described with respect to FIG. 32.

In aspects, the heat sink 502 may be implemented as a channel mount structure. In particular, the heat sink 502 may extend between implementations of the at least one component 504 as well as below implementations of the at least one component 504.

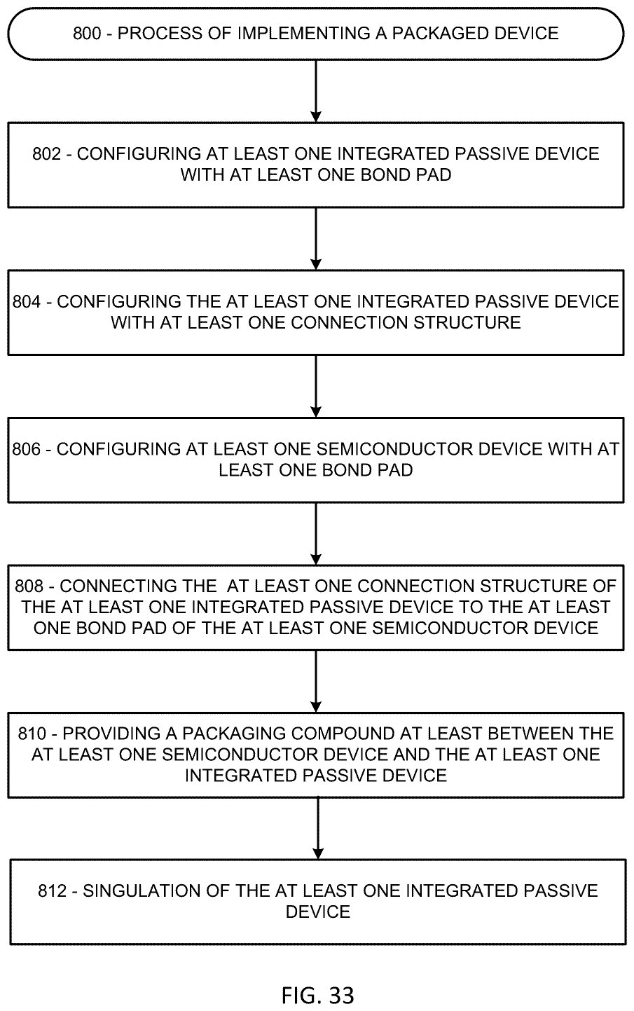

FIG. 33 shows an exemplary process of implementing a packaged device according to aspects of the disclosure.

In particular, FIG. 33 shows an exemplary process of implementing a packaged device 800 according to aspects of the disclosure. In particular, it should be noted that the process of implementing a packaged device 800 is merely exemplary and may be modified consistent with the various aspects disclosed herein. Moreover, the process of implementing a packaged device 800 of the disclosure may include a process of manufacturing the packaged device 100. It should be noted that the process of implementing a packaged device 800 may be performed in a different order consistent with the aspects described above. Moreover, the process of implementing a packaged device 800 may be modified to have more or fewer process steps consistent with the various aspects disclosed herein.

The process of implementing a packaged device 800 of the disclosure may include configuring at least one integrated passive device with at least one bond pad 802. In this regard, the configuring at least one integrated passive device with at least one bond pad 802 may include any one or more materials, structures, arrangements, processes, and/or the like as described herein. Moreover, one or more proceeding or subsequent processes may also be implemented with respect to the configuring at least one integrated passive device with at least one bond pad 802 consistent with the disclosure.

In particular aspects, the configuring at least one integrated passive device with at least one bond pad 802 may include configuring the at least one integrated passive device 200 with the at least one bond pad 202. In particular aspects, the configuring at least one integrated passive device with at least one bond pad 802 may include the exemplary process flow 300 as illustrated in FIG. 5.

The process of implementing a packaged device 800 of the disclosure may include configuring the at least one integrated passive device with at least one connection structure 804. In this regard, the configuring the at least one integrated passive device with at least one connection structure 804 may include any one or more materials, structures, arrangements, processes, and/or the like as described herein. Moreover, one or more proceeding or subsequent processes may also be implemented with respect to the configuring the at least one integrated passive device with at least one connection structure 804 consistent with the disclosure.

In particular aspects, the configuring the at least one integrated passive device with at least one connection structure 804 may include configuring the at least one integrated passive device 200 with the at least one connection structure 204. In particular aspects, the configuring the at least one integrated passive device with at least one connection structure 804 may include the exemplary process flow 300 as illustrated in FIG. 5.

The process of implementing a packaged device 800 of the disclosure may include configuring at least one semiconductor device with at least one bond pad 806. In this regard, the configuring at least one semiconductor device with at least one bond pad 806 may include any one or more materials, structures, arrangements, processes, and/or the like as described herein. Moreover, one or more proceeding or subsequent processes may also be implemented with respect to the configuring at least one semiconductor device with at least one bond pad 806 consistent with the disclosure.

In particular aspects, the configuring at least one semiconductor device with at least one bond pad 806 may include configuring the at least one semiconductor device 400 with the at least one bond pad 402. In particular aspects, the configuring at least one semiconductor device with at least one bond pad 806 may include the exemplary process flow 310 as illustrated in FIG. 13.

The process of implementing a packaged device 800 of the disclosure may include connecting the at least one connection structure of the at least one integrated passive device to the at least one bond pad of the at least one semiconductor device 808. In this regard, the connecting the at least one connection structure of the at least one integrated passive device to the at least one bond pad of the at least one semiconductor device 808 may include any one or more materials, structures, arrangements, processes, and/or the like as described herein. Moreover, one or more proceeding or subsequent processes may also be implemented with respect to the connecting the at least one connection structure of the at least one integrated passive device to the at least one bond pad of the at least one semiconductor device 808 consistent with the disclosure.

In particular aspects, the connecting the at least one connection structure of the at least one integrated passive device to the at least one bond pad of the at least one semiconductor device 808 may include connecting the at least one connection structure 204 of the at least one integrated passive device 200 to the at least one bond pad 402 of the at least one semiconductor device 400. In particular aspects, the connecting the at least one connection structure of the at least one integrated passive device to the at least one bond pad of the at least one semiconductor device 808 may include the exemplary wafer level processing of a wafer of the at least one integrated passive device 320 and/or the at least one semiconductor device attachment to the wafer of the at least one integrated passive device process 323 and/or the exemplary wafer level processing of a wafer of the at least one integrated passive device 340 of FIG. 20 and/or the attachment of the at least one semiconductor device attachment to the wafer of the at least one integrated passive device process 323 of FIG. 22.

The process of implementing a packaged device 800 of the disclosure may include providing a packaging compound at least between the at least one semiconductor device and the at least one integrated passive device 810. In this regard, the providing a packaging compound at least between the at least one semiconductor device and the at least one integrated passive device 810 may include any one or more materials, structures, arrangements, processes, and/or the like as described herein. Moreover, one or more proceeding or subsequent processes may also be implemented with respect to the providing a packaging compound at least between the at least one semiconductor device and the at least one integrated passive device 810 consistent with the disclosure.

In particular aspects, the providing a packaging compound at least between the at least one semiconductor device and the at least one integrated passive device 810 may include providing the packaging compound 102 at least between the at least one semiconductor device 400 and the at least one integrated passive device 200. In particular aspects, the providing a packaging compound at least between the at least one semiconductor device and the at least one integrated passive device 810 may include the molding of the wafer of the at least one integrated passive device process 324 of FIG. 20 and/or the implementing an underfill of the wafer of the at least one integrated passive device 327 of FIG. 22.

In one exemplary method, the at least one semiconductor device 400 can be molded to the wafer accommodating a plurality of implementations of the at least one integrated passive device 200 using vacuum assisted molding. This may create a blanket, void-free encapsulation of the at least one semiconductor device 400 attached to the IPD wafer accommodating a plurality of implementations of the at least one integrated passive device 200. For this method, the IPD wafer dicing may include dicing through the wafer level molding to obtain individual implementations of the at least one integrated passive device 200 having the at least one semiconductor device 400 thereon.

Alternatively, the at least one semiconductor device 400 can be individually underfilled using capillary underfill, relying on natural capillary vacuum to draw the underfill epoxy only through a bond line of the die. In this aspect, dicing streets of the IPD wafer accommodating a plurality of implementations of the at least one integrated passive device 200 may be left clear for standard SiC dicing.

The process of implementing a packaged device 800 of the disclosure may include singulation of the at least one integrated passive device 812. In this regard, the providing a packaging compound at least between the at least one semiconductor device and the singulation of the at least one integrated passive device 812 may include any one or more materials, structures, arrangements, processes, and/or the like as described herein. Moreover, one or more proceeding or subsequent processes may also be implemented with respect to the singulation of the at least one integrated passive device 812 consistent with the disclosure.

In particular aspects, the singulation of the at least one integrated passive device 812 may include singulation of the at least one integrated passive device 200. In particular aspects, the singulation of the at least one integrated passive device 812 may include the singluation of wafer of the at least one integrated passive device process 326 of FIG. 21 and/or the singluation of wafer of the at least one integrated passive device process 326 of FIG. 22.

Aspects of the packaged device 100 illustrated in FIGS. 1-29 and described in the associated description thereof may include and/or may optionally include any one or more the following nonlimiting aspects:

In aspects, the disclosure enables stacking the at least one semiconductor device 400 on the at least one integrated passive device 200 and provides a way to realize wafer level packaging for the packaged device 100 for applications, such as RF power applications. The stack up helps to achieve good radio frequency (RF) performance, thermal performance, and/or the like. The disclosed approach also offers a way to bump the at least one semiconductor device 400 and reduce assembly and manufacturing cost.

In aspects, by changing the at least one bond pad 402 metal stack up and making it compatible with a soldering reflow process, the disclosed device and process allows attaching thin implementations of the at least one semiconductor device 400, like 75 or 100 μm dies, onto the at least one integrated passive device 200 in an IPD wafer through bumping. Such approach allows the at least one bond pad 202 processed on a 6 or 8 inch IPD wafer, which may be based on SiC wafer or silicon (Si) wafer. By attaching the at least one semiconductor device 400 on the at least one integrated passive device 200 of the IPD wafer first, then singulation, the disclosed process provides a way to achieve wafer level packaging of the packaged device 100, which helps to reduce manufacturing cost, improve product yield, and/or the like.

Aspects of the disclosed process and device may utilize wafer level processing (WLP) to form the at least one connection structure 204 as one or more bumps or copper pillars on IPD wafers. In aspects, the disclosed process may include first bumping the at least one integrated passive device 200 with the at least one bond pad 202 and/or the at least one connection structure 204. In aspects of the disclosure, the processing may begin with under bump metals (UBM), depositing seed metal such as titanium (Ti), Tungsten-titanium (TiW), and/or the like for adhesion, followed by copper (Cu) for electrical continuity.

In aspects, the at least one bond pad 202 and/or the at least one connection structure 204 may be implemented as one or more bumps or copper pillars that may be implemented as electroplated bumps or pillars. For electroplated bumps or pillars, the wafer the at least one integrated passive device 200 may be photopatterned to create a plating template.

In aspects for implementation of the at least one bond pad 202 and/or the at least one integrated passive device 200 as one or more bumps or copper pillars with solders, the plating may generally include an approximately 2 μm nickel (Ni) barrier under or immediately under the solder to prevent metal migration.

In aspects of the at least one connection structure 204 implemented as Cu pillars, the Cu pedestal may be plated in the same template prior to plating Ni and solder. Once the at least one connection structure 204, such as the bumps or pillars, are plated, a resist may be stripped in a solvent and a blanket seed metal may be etched back to clear the field. Thereafter, the disclosed process may implement reflow of the solder portion 218, such as a plated solder implementation, to form the at least one connection structure 204 as domed bumps ready for bonding.

Aspects of the disclosed process and device may utilize WLP for forming the at least one bond pad 402 as pads, such as Ni pads, gold (Au) pads, and/or the like on the active device wafer of the at least one semiconductor device 400, such as GaNSiC wafers.

In aspects, the wafers of the at least one semiconductor device 400 may be processed to form the at least one bond pad 402 as complementary bond pads to the at least one bond pad 202 or bumped structures on the at least one integrated passive device 200. In aspects, the disclosed process can be accomplished using similar processing to the at least one integrated passive device 200. For example, depositing seed metal such as titanium (Ti), Tungsten-titanium (TiW), and/or the like for adhesion, followed by copper (Cu) for electrical continuity. Thereafter, the at least one semiconductor device 400 may be photopatterned. Further, the at least one bond pad 402, such as Ni pads and/or Au pads, are electroplated in the template. In aspects, the Ni pads may be approximately 2 μm and the Au pads may be approximately 0.25 μm.

Thereafter, the resist and the seed metal may then be stripped back in the same fashion as the at least one integrated passive device 200. The choice of Ni pad thickness may be based on the need for a barrier to metal migration; and a choice of Au pad thickness may be based on a need to prevent oxidation and allow for proper wetting to the solder portion 218 during die attach of the at least one semiconductor device 400 to the at least one connection structure 204 of the at least one integrated passive device 200. In other aspects, the at least one connection structure 204 may be deposited using electroless plating baths, which may eliminate the need for seed metal or seed metal strip.

Aspects of the disclosed device and process may further utilize hybridization, molding, singulation, and/or the like of resulting assemblies of the at least one integrated passive device 200 and the at least one semiconductor device 400.

In aspects, upon completion of all wafer level processing of the at least one semiconductor device 400, the wafers may then be diced. Individual active device die implementations of the at least one semiconductor device 400 may be aligned to a full IPD wafer having a plurality of the at least one integrated passive device 200 to allow for wafer level reflow, a batch die attach process, and/or the like.

Following die attach of the at least one semiconductor device 400 to the at least one connection structure 204 of the at least one integrated passive device 200, it may be beneficial to provide the packaging compound 102, such as to apply an epoxy to structurally support the bond and lock the at least one semiconductor device 400 in place on the at least one integrated passive device 200. This can be accomplished using a number of methods.

In one exemplary method, the at least one semiconductor device 400 can be molded to the wafer accommodating a plurality of implementations of the at least one integrated passive device 200 using vacuum assisted molding. This may create a blanket, void-free encapsulation of the at least one semiconductor device 400 attached to the IPD wafer accommodating a plurality of implementations of the at least one integrated passive device 200. For this method, the IPD wafer dicing may include dicing through the wafer level molding to obtain individual implementations of the at least one integrated passive device 200 having the at least one semiconductor device 400 thereon.

Alternatively, the at least one semiconductor device 400 can be individually underfilled using capillary underfill, relying on natural capillary vacuum to draw the underfill epoxy only through a bond line of the die. In this aspect, dicing streets of the IPD wafer accommodating a plurality of implementations of the at least one integrated passive device 200 may be left clear for standard SiC dicing.

Aspects of the disclosed device and process may utilize multiple active die implementations of the at least one semiconductor device 400 arranged on the at least one integrated passive device 200 that may be configured as an IPD interposer after singulation. Such implementations may be design dependent. The assembly of the at least one integrated passive device 200 and the at least one semiconductor device 400 may then be incorporated into a full package using the at least one solder ball connection 230.

Aspects of the disclosed device and process may implement single or multiple die implementations of the at least one semiconductor device 400, such as single or multiple GaNSiC dies on an implementation of the at least one integrated passive device 200 as an IPD chip or interposer. In aspects, the at least one integrated passive device 200 and/or the at least one semiconductor device 400 may include bumps on interconnect pads to allow stacked chips connecting to a next level package. In aspects, solder paste printing may be used on the packaged device 100, the at least one integrated passive device 200, and/or the at least one semiconductor device 400 for connecting. When such assembly flow is used, bumps on stacked chip interconnect pads may not be required.

In aspects, the at least one integrated passive device 200 may be attached to the at least one component 504, such as a circuit board (PCB), for example by the at least one solder ball connection 230. In aspects, the assembly the at least one integrated passive device 200 and the at least one semiconductor device 400 may be aligned such that the back side of the at least one semiconductor device 400 contacts the heat sink 502 or flange with a conductive adhesive.

In aspects, the packaged device 100 may have the at least one semiconductor device 400 attached to the at least one component 504, such as a PCB, via the at least one solder ball connection 230. The assembly would be aligned such that the backside the at least one semiconductor device 400 contacts the heat sink 502 or flange with a conductive adhesive.

Aspects of the disclosed implementation of the packaged device 100 process device may be utilized for any applications, such as any RF power applications, which may benefit from vertical integration for better electrical performance, thermal performance, and/or the like. In aspects, the packaged device 100 may be implemented as a RF package, a RF amplifier package, a RF power amplifier package, a RF power transistor package, a RF power amplifier transistor package, and/or the like as described herein.

In aspects, the at least one connection structure 204 may be arranged on the at least one integrated passive device 200 while the at least one integrated passive device 200 may be arranged in a wafer together with a plurality of the at least one integrated passive device 200 prior to singulation of the at least one integrated passive device 200 from the wafer. In aspects, the at least one semiconductor device 400 may be arranged on the at least one connection structure 204 of the at least one integrated passive device 200 while the at least one integrated passive device 200 may be arranged in a wafer together with a plurality of the at least one integrated passive device 200 prior to singulation of the at least one integrated passive device 200 from the wafer. In aspects, the solder portion 218 may be arranged on an end of the at least one connection structure 204 closer to the at least one bond pad 402 of the at least one semiconductor device 400 than the at least one bond pad 202 of the at least one integrated passive device 200. In aspects, the solder portion 218 may be arranged on an end of the at least one connection structure 204 distal from the at least one integrated passive device 200. In aspects, the solder portion 218 may be arranged on an end of the at least one connection structure 204 distal from the at least one bond pad 202 of the at least one integrated passive device 200. In aspects, the solder portion 218 may be arranged on an end of the at least one connection structure 204 proximal to the at least one semiconductor device 400. In aspects, the solder portion 218 may be arranged on an end of the at least one connection structure 204 proximal to the at least one bond pad 402 of the at least one semiconductor device 400.

In aspects, the packaged device 100 may be configured such that the solder portion 218 is arranged on an end of the at least one connection structure 204 closer to the at least one semiconductor device 400 than the at least one bond pad of the at least one integrated passive device 200; and the at least one connection structure 204 comprises a pillar portion that comprises an electroplated copper structure and/or an electroless plated copper structure. In aspects, the packaged device 100 may be configured such that the solder portion 218 comprises a printed solder paste. In aspects, the packaged device 100 may be configured such that the pillar portion comprises an electroplated copper structure and/or an electroless plated copper structure; and the solder portion 218 comprises a printed solder paste.

In aspects, the packaged device 100 may be configured such that the pillar portion comprises an electroplated copper structure and/or an electroless plated copper structure; and the pillar portion further comprises a nickel (Ni) barrier layer portion arranged between the solder portion 218 and the pillar portion. In aspects, the packaged device 100 may include arranging the solder portion 218 on an end of the at least one connection structure 204 closer to the at least one semiconductor device 400 than the at least one bond pad of the at least one integrated passive device 200; and forming the at least one connection structure 204 as a pillar portion with an electroplated copper structure and/or an electroless plated copper structure.

In aspects, the packaged device 100 may include printing the solder portion 218 with a solder paste. In aspects, the packaged device 100 may include forming the at least one connection structure 204 as a pillar portion with an electroplated copper structure and/or an electroless plated copper structure; and printing the solder portion 218 onto the pillar portion with a solder paste. In aspects, the packaged device 100 may include forming the at least one connection structure 204 as a pillar portion with an electroplated copper structure and/or an electroless plated copper structure; and; and arranging a nickel (Ni) barrier layer portion between the solder portion 218 and the pillar portion.

In aspects, the at least one semiconductor device 400 may be implemented a gallium nitride (GaN) silicon carbide (SiC) transistor. In aspects, the at least one semiconductor device 400 may be implemented as one or more of a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), one or more laterally-diffused metal-oxide semiconductor (LDMOS) transistors, a Bipolar Junction Transistor (BJT), an Insulated Gate Bipolar Transistor (IGBT), a high-electron-mobility transistor (HEMT), a Wide Band Gap (WBG) semiconductor, a power module, a gate driver, a component such as a General-Purpose Broadband component, a Telecom component, a L-Band component, a S-Band component, a X-Band component, a C-Band component, a Ku-Band component, a Satellite Communications component, a Doherty configuration, and/or the like. Additionally, the at least one semiconductor device 400 may include one or more transistor dies that may include GaN based transistors, Metal Semiconductor Field-Effect transistors (MESFET), Metal Oxide Field Effect Transistors (MOSFET), Junction Field Effect Transistors (JFET), Bipolar Junction Transistors (BJT), Insulated Gate Bipolar Transistors (IGBT), high-electron-mobility transistors (HEMT), Wide Band Gap (WBG) transistors, and/or the like.

In aspects, the packaging compound 102 may be formed of a plastic, a mold compound, a plastic compound, a polymer, a polymer compound, a plastic polymer compound, an epoxy compound, a silicone compound, and/or the like. The packaging compound 102 may be injection molded, transfer molded, and/or compression molded around, the at least one integrated passive device 200, the at least one semiconductor device 400, and other components of the packaged device 100 from the outside environment. The packaging compound 102 may include underfill between the at least one semiconductor device 400 and the at least one integrated passive device 200. In aspects, the packaging compound 102 may be implemented with different materials, may be applied in one or more different steps, and/or the like. In aspects, the packaging compound 102 may be implemented with different materials, may be applied in one or more different steps, and/or the like for a portion of the underfill and a portion around the at least one semiconductor device 400.

In aspects, the packaging compound 102 may be implemented first with a different softer material for a portion of the underfill to reduce components of the packaged device 100 from being dislocated, disconnected, popped, and/or the like when exposed to higher temperatures due to a coefficient of thermal expansion (CTE) of various components of the packaged device 100; and a portion around the at least one semiconductor device 400 may include a harder material.

The packaged device 100 may be implemented as an RF package and the at least one semiconductor device 400 may be implemented as a radio frequency device that may include, connect, support, or the like a transmitter, transmitter functions, a receiver, receiver functions, a transceiver, transceiver functions, matching network functions, harmonic termination circuitry, integrated passive devices (IPD), and the like. the at least one semiconductor device 400 may be implemented as a radio frequency device may be configured to, may support, or the like transmitting a radio wave and modulating that wave to carry data with allowable transmitter power output, harmonics, and/or band edge requirements. The at least one semiconductor device 400 device may be configured to, may support, or the like receiving a radio wave and demodulating the radio wave. The at least one semiconductor device 400 implemented as a radio frequency device may be configured to, may support, or the like transmitting a radio wave and modulating that wave to carry data with allowable transmitter power output, harmonics, and/or band edge requirements; and may be configured to, may support, or the like receiving a radio wave and demodulating the radio wave.

In some aspects, the at least one integrated passive device 200 and/or the at least one semiconductor device 400 may include a substrate that may be a semi-insulating SiC substrate, a p-type substrate, an n-type substrate, and/or the like. In some aspects, the substrate may be very lightly doped. In one aspect, the substrate may be formed of SiC selected from the group of 6H, 4H, 15R, 3C SiC, or the like. In one aspect, the substrate may be formed of SiC that may be semi-insulating and doped with vanadium or any other suitable dopant or undoped of high purity with defects providing the semi-insulating properties. In other aspects, the substrate may include silicon, Alumina, Aluminum Nitride (AlN), Beryllium oxide (BeO), Titanium Oxide (TiO), metal-oxide substrates, high dielectric metal-oxide substrates, high dielectric substrates, thermally conductive high dielectric materials/substrates, and/or other similar thermal conductivity performance dielectric material.

The at least one via 226 may be metallic plated holes or metallic filled holes that may function as electrical tunnels through the substrate of the at least one integrated passive device 200; and the at least one via 526 may be metallic plated holes or metallic filled holes that may function as electrical tunnels through the substrate of the at least one component 504. The vias may comprise a metallic material such as copper, gold, nickel, palladium, silver, tin, a gold tin alloy, and the like, and combinations thereof.

In additional aspects, the at least one integrated passive device 200 may include one or more circuits, reactive components, inductors, resistors, and/or the like. The at least one integrated passive device 200 may be configured as or as part of an output impedance matching network, an input impedance matching network, a higher order harmonic termination circuit, a fundamental frequency matching circuit, and/or the like.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

Accordingly, the disclosure has set forth processes and configurations to address process capability limitations and material properties of SiC with various implementations, configurations, structures, processes, and/or the like of the packaged device 100, the at least one integrated passive device 200, the at least one semiconductor device 400, associated structure thereof, and/or the like as disclosed herein.

The following are a number of nonlimiting EXAMPLES of aspects of the disclosure.

One EXAMPLE: a packaged device includes at least one integrated passive device that includes at least one bond pad. The packaged device in addition includes at least one semiconductor device that includes at least one bond pad. The device moreover includes at least one connection structure arranged on the at least one integrated passive device. The device also includes where the at least one connection structure includes a solder portion configured to form a solder connection to the at least one bond pad of the at least one semiconductor device.

The above-noted EXAMPLE may further include any one or a combination of more than one of the following EXAMPLES:

The packaged device of the above-noted EXAMPLE where the solder portion is arranged on an end of the at least one connection structure closer to the at least one bond pad of the at least one semiconductor device than the at least one bond pad of the at least one integrated passive device. The packaged device of the above-noted EXAMPLE where the solder portion is arranged on an end of the at least one connection structure closer to the at least one semiconductor device than the at least one bond pad of the at least one integrated passive device; and where the at least one connection structure includes a pillar portion that includes an electroplated copper structure and/or an electroless plated copper structure. The packaged device of the above-noted EXAMPLE where the solder portion is arranged on an end of the at least one connection structure distal from the at least one integrated passive device. The packaged device of the above-noted EXAMPLE where the solder portion is arranged on an end of the at least one connection structure distal from the at least one bond pad of the at least one integrated passive device. The packaged device of the above-noted EXAMPLE where the solder portion is arranged on an end of the at least one connection structure opposing the at least one semiconductor device. The packaged device of the above-noted EXAMPLE where the solder portion is arranged on an end of the at least one connection structure opposing the at least one bond pad of the at least one semiconductor device. The packaged device of the above-noted EXAMPLE where the solder portion is arranged on an end of the at least one connection structure; and where the solder portion includes reflowed solder. The packaged device of the above-noted EXAMPLE where the at least one connection structure is attached to the at least one integrated passive device while the at least one integrated passive device is arranged in a wafer together with a plurality of the at least one integrated passive device prior to singulation of the at least one integrated passive device from the wafer. The packaged device of the above-noted EXAMPLE where the at least one semiconductor device is arranged on the at least one connection structure of the at least one integrated passive device while the at least one integrated passive device is arranged in a wafer together with a plurality of the at least one integrated passive device prior to singulation of the at least one integrated passive device from the wafer. The packaged device of the above-noted EXAMPLE where the at least one connection structure is arranged on the at least one bond pad of the at least one integrated passive device during wafer processing of the at least one integrated passive device. The packaged device of the above-noted EXAMPLE where the at least one semiconductor device is connected to the at least one connection structure of the at least one integrated passive device during wafer processing of the at least one integrated passive device. The packaged device of the above-noted EXAMPLE where the at least one connection structure is arranged on the at least one bond pad of the at least one integrated passive device prior to being connected to the at least one bond pad of the at least one semiconductor device. The packaged device of the above-noted EXAMPLE where the at least one connection structure is configured to extend vertically below the at least one integrated passive device and connect to the at least one bond pad of the at least one semiconductor device. The packaged device of the above-noted EXAMPLE where the at least one bond pad is arranged on a first surface of the at least one integrated passive device; and where the at least one integrated passive device is configured as a flip chip such that the first surface is located adjacent the at least one semiconductor device. The packaged device of the above-noted EXAMPLE where the at least one connection structure includes a pillar portion and a solder portion. The packaged device of the above-noted EXAMPLE where the pillar portion includes an electroplated metallic structure and/or an electroless plated metallic structure. The packaged device of the above-noted EXAMPLE where the pillar portion includes an electroplated copper structure and/or an electroless plated copper structure. The packaged device of the above-noted EXAMPLE where the solder portion includes a printed solder paste. The packaged device of the above-noted EXAMPLE where the pillar portion includes an electroplated copper structure and/or an electroless plated copper structure; and where the solder portion includes a printed solder paste. The packaged device of the above-noted EXAMPLE where the pillar portion includes an electroplated copper structure and/or an electroless plated copper structure; and where the pillar portion further includes a nickel (Ni) barrier layer portion arranged between the solder portion and the pillar portion. The packaged device of the above-noted EXAMPLE where the at least one connection structure includes a layer portion arranged between the solder portion and the pillar portion. The packaged device of the above-noted EXAMPLE where the at least one semiconductor device includes a gallium nitride (GaN) silicon carbide (SiC) transistor. The packaged device of the above-noted EXAMPLE where the at least one integrated passive device includes a silicon carbide (SIC) integrated passive device (IPD). The packaged device of the above-noted EXAMPLE includes a packaging compound, where the packaging compound is arranged between the at least one integrated passive device and the at least one semiconductor device; and where the packaging compound includes an epoxy, a molding material, and/or a mold compound. The packaged device of the above-noted EXAMPLE where the packaging compound is configured as an underfill between the at least one integrated passive device and the at least one semiconductor device. The packaged device of the above-noted EXAMPLE where the packaging compound is arranged to surround one or more implementations of the at least one connection structure. The packaged device of the above-noted EXAMPLE includes at least one solder ball connection arranged on at least one implementation of the at least one bond pad of the at least one integrated passive device. The packaged device of the above-noted EXAMPLE where the at least one bond pad of the at least one integrated passive device includes one or more under bump metals (UBM). The packaged device of the above-noted EXAMPLE where the one or more under bump metals (UBM) includes titanium (Ti), Tungsten-titanium (TiW), and/or copper (Cu). The packaged device of the above-noted EXAMPLE where the at least one bond pad arranged on the at least one semiconductor device includes one or more under bump metals (UBM). The packaged device of the above-noted EXAMPLE where the one or more under bump metals (UBM) includes titanium (Ti), Tungsten-titanium (TiW), and/or copper (Cu). The packaged device of the above-noted EXAMPLE where the at least one semiconductor device includes multiple implementations of the at least one semiconductor device. The packaged device of the above-noted EXAMPLE includes a heat sink and the at least one semiconductor device is attached to the heat sink to transfer heat to the heat sink. The packaged device of the above-noted EXAMPLE includes at least one component, where the at least one component is electrically connected to the at least one integrated passive device. The packaged device of the above-noted EXAMPLE where the at least one component includes at least one surface mount device (SMD). The packaged device of the above-noted EXAMPLE where the at least one component is connected to the heat sink to transfer heat to the heat sink.

One EXAMPLE: a process includes configuring at least one integrated passive device with at least one bond pad. The process in addition includes configuring at least one semiconductor device with at least one bond pad. The process moreover includes arranging at least one connection structure on the at least one integrated passive device. The process also includes arranging a solder portion on the at least one connection structure. The process further includes connecting the at least one connection structure to the at least one bond pad of the at least one semiconductor device with the solder portion.

The above-noted EXAMPLE may further include any one or a combination of more than one of the following EXAMPLES:

The process of the above-noted EXAMPLE includes arranging the solder portion on an end of the at least one connection structure closer to the at least one bond pad of the at least one semiconductor device than the at least one bond pad of the at least one integrated passive device. The process of the above-noted EXAMPLE where the solder portion is arranged on an end of the at least one connection structure closer to the at least one semiconductor device than the at least one bond pad of the at least one integrated passive device; and where the at least one connection structure includes a pillar portion that includes an electroplated copper structure and/or an electroless plated copper structure. The process of the above-noted EXAMPLE arranging the solder portion on an end of the at least one connection structure closer to the at least one semiconductor device than the at least one bond pad of the at least one integrated passive device; and forming the at least one connection structure as a pillar portion with an electroplated copper structure and/or an electroless plated copper structure. The process of the above-noted EXAMPLE includes arranging the solder portion on an end of the at least one connection structure distal from the at least one integrated passive device. The process of the above-noted EXAMPLE includes arranging the solder portion on an end of the at least one connection structure distal from the at least one bond pad of the at least one integrated passive device. The process of the above-noted EXAMPLE includes arranging the solder portion on an end of the at least one connection structure opposing the at least one semiconductor device. The process of the above-noted EXAMPLE includes arranging the solder portion on an end of the at least one connection structure opposing the at least one bond pad of the at least one semiconductor device. The process of the above-noted EXAMPLE where the solder portion is arranged on an end of the at least one connection structure; and where the solder portion includes reflowed solder. The process of the above-noted EXAMPLE includes: arranging the solder portion on an end of the at least one connection structure; and subsequently reflowing the solder portion. The process of the above-noted EXAMPLE includes attaching the at least one connection structure to the at least one integrated passive device while the at least one integrated passive device is arranged in a wafer together with a plurality of the at least one integrated passive device prior to singulation of the at least one integrated passive device from the wafer. The process of the above-noted EXAMPLE includes: attaching the at least one connection structure to the at least one integrated passive device while the at least one integrated passive device is arranged in a wafer together with a plurality of the at least one integrated passive device; and subsequently singulating the at least one integrated passive device from the wafer. The process of the above-noted EXAMPLE includes arranging the at least one semiconductor device on the at least one connection structure of the at least one integrated passive device while the at least one integrated passive device is arranged in a wafer together with a plurality of the at least one integrated passive device prior to singulation of the at least one integrated passive device from the wafer. The process of the above-noted EXAMPLE includes: arranging the at least one semiconductor device on the at least one connection structure of the at least one integrated passive device while the at least one integrated passive device is arranged in a wafer together with a plurality of the at least one integrated passive device; and subsequently singulating the at least one integrated passive device from the wafer. The process of the above-noted EXAMPLE includes arranging the at least one connection structure on the at least one bond pad of the at least one integrated passive device during wafer processing of the at least one integrated passive device. The process of the above-noted EXAMPLE includes connecting the at least one semiconductor device to the at least one connection structure of the at least one integrated passive device during wafer processing of the at least one integrated passive device. The process of the above-noted EXAMPLE includes arranging the at least one connection structure on the at least one bond pad of the at least one integrated passive device prior to being connected to the at least one bond pad of the at least one semiconductor device. The process of the above-noted EXAMPLE where the at least one connection structure is configured to extend vertically below the at least one integrated passive device and connect to the at least one bond pad of the at least one semiconductor device. The process of the above-noted EXAMPLE where the at least one bond pad is arranged on a first surface of the at least one integrated passive device; and where the at least one integrated passive device is configured as a flip chip such that the first surface is located adjacent the at least one semiconductor device. The process of the above-noted EXAMPLE includes forming the at least one connection structure with a pillar portion and a solder portion. The process of the above-noted EXAMPLE includes forming the pillar portion with an electroplated metallic structure and/or an electroless plated metallic structure. The process of the above-noted EXAMPLE includes forming the pillar portion with an electroplated copper structure and/or an electroless plated copper structure. The process of the above-noted EXAMPLE where the at least one connection structure includes a layer portion arranged between the solder portion and the pillar portion. The process of the above-noted EXAMPLE where the solder portion includes a printed solder paste. The process of the above-noted EXAMPLE includes printing the solder portion with a solder paste. The process of the above-noted EXAMPLE includes: forming the at least one connection structure as a pillar portion with an electroplated copper structure and/or an electroless plated copper structure; and printing the solder portion onto the pillar portion with a solder paste. The process of the above-noted EXAMPLE where the at least one connection structure includes a pillar portion that includes an electroplated copper structure and/or an electroless plated copper structure; and where the pillar portion further includes a nickel (Ni) barrier layer portion arranged between the solder portion and the pillar portion. The process of the above-noted EXAMPLE forming the at least one connection structure as a pillar portion with an electroplated copper structure and/or an electroless plated copper structure; and; and arranging a nickel (Ni) barrier layer portion between the solder portion and the pillar portion. The process of the above-noted EXAMPLE where the at least one semiconductor device includes a gallium nitride (GaN) silicon carbide (SIC) transistor. The process of the above-noted EXAMPLE where the at least one integrated passive device includes a silicon carbide (SiC) integrated passive device (IPD). The process of the above-noted EXAMPLE includes arranging a packaging compound between the at least one integrated passive device and the at least one semiconductor device, where the packaging compound includes an epoxy, a molding material, and/or a mold compound. The process of the above-noted EXAMPLE includes configuring the packaging compound as an underfill between the at least one integrated passive device and the at least one semiconductor device. The process of the above-noted EXAMPLE includes arranging the packaging compound to surround one or more implementations of the at least one connection structure. The process of the above-noted EXAMPLE includes arranging at least one solder ball connection on at least one implementation of the at least one bond pad of the at least one integrated passive device. The process of the above-noted EXAMPLE includes forming the at least one bond pad of the at least one integrated passive device with one or more under bump metals (UBM). The process of the above-noted EXAMPLE where the one or more under bump metals (UBM) includes titanium (Ti), Tungsten-titanium (TiW), and/or copper (Cu). The process of the above-noted EXAMPLE includes forming the at least one bond pad arranged on the at least one semiconductor device with one or more under bump metals (UBM). The process of the above-noted EXAMPLE where the one or more under bump metals (UBM) includes titanium (Ti), Tungsten-titanium (TiW), and/or copper (Cu). The process of the above-noted EXAMPLE where the at least one semiconductor device includes multiple implementations of the at least one semiconductor device. The process of the above-noted EXAMPLE includes attaching a heat sink to the at least one semiconductor device to transfer heat to the heat sink. The process of the above-noted EXAMPLE includes electrically connecting at least one component to the at least one integrated passive device. The process of the above-noted EXAMPLE where the at least one component includes at least one surface mount device (SMD). The process of the above-noted EXAMPLE includes connecting the at least one component to the heat sink to transfer heat to the heat sink.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure.

1. A packaged device comprising:
at least one integrated passive device comprising at least one bond pad;
at least one semiconductor device comprising at least one bond pad; and
at least one connection structure arranged on the at least one integrated passive device,
wherein the at least one connection structure comprises a solder portion configured to form a solder connection to the at least one bond pad of the at least one semiconductor device.

2. The packaged device according to claim 1 wherein the solder portion is arranged on an end of the at least one connection structure closer to the at least one bond pad of the at least one semiconductor device than the at least one bond pad of the at least one integrated passive device.

3. The packaged device according to claim 1
wherein the solder portion is arranged on an end of the at least one connection structure closer to the at least one semiconductor device than the at least one bond pad of the at least one integrated passive device; and
wherein the at least one connection structure comprises a pillar portion that comprises an electroplated copper structure and/or an electroless plated copper structure.

4. The packaged device according to claim 1 wherein the solder portion is arranged on an end of the at least one connection structure distal from the at least one integrated passive device.

5. The packaged device according to claim 1 wherein the solder portion is arranged on an end of the at least one connection structure distal from the at least one bond pad of the at least one integrated passive device.

6. The packaged device according to claim 1 wherein the solder portion is arranged on an end of the at least one connection structure opposing the at least one semiconductor device.

7. The packaged device according to claim 1 wherein the solder portion is arranged on an end of the at least one connection structure opposing the at least one bond pad of the at least one semiconductor device.

8. The packaged device according to claim 1 wherein the solder portion is arranged on an end of the at least one connection structure; and wherein the solder portion comprises reflowed solder.

9. The packaged device according to claim 1 wherein the at least one connection structure is attached to the at least one integrated passive device while the at least one integrated passive device is arranged in a wafer together with a plurality of the at least one integrated passive device prior to singulation of the at least one integrated passive device from the wafer.

10. The packaged device according to claim 1 wherein the at least one semiconductor device is arranged on the at least one connection structure of the at least one integrated passive device while the at least one integrated passive device is arranged in a wafer together with a plurality of the at least one integrated passive device prior to singulation of the at least one integrated passive device from the wafer.

11. The packaged device according to claim 1 wherein the at least one connection structure is arranged on the at least one bond pad of the at least one integrated passive device during wafer processing of the at least one integrated passive device.

12. The packaged device according to claim 1 wherein the at least one semiconductor device is connected to the at least one connection structure of the at least one integrated passive device during wafer processing of the at least one integrated passive device.

13. The packaged device according to claim 1 wherein the at least one connection structure is arranged on the at least one bond pad of the at least one integrated passive device prior to being connected to the at least one bond pad of the at least one semiconductor device.

14. The packaged device according to claim 1 wherein the at least one connection structure is configured to extend vertically below the at least one integrated passive device and connect to the at least one bond pad of the at least one semiconductor device.

15. The packaged device according to claim 1 wherein the at least one bond pad is arranged on a first surface of the at least one integrated passive device; and wherein the at least one integrated passive device is configured as a flip chip such that the first surface is located adjacent the at least one semiconductor device.

16. The packaged device according to claim 1 wherein the at least one connection structure comprises a pillar portion and a solder portion.

17. The packaged device according to claim 16 wherein the pillar portion comprises an electroplated metallic structure and/or an electroless plated metallic structure.

18. The packaged device according to claim 16 wherein the pillar portion comprises an electroplated copper structure and/or an electroless plated copper structure.

19. The packaged device according to claim 16 wherein the solder portion comprises a printed solder paste.

20. The packaged device according to claim 16
wherein the pillar portion comprises an electroplated copper structure and/or an electroless plated copper structure; and
wherein the solder portion comprises a printed solder paste.

21. The packaged device according to claim 16
wherein the pillar portion comprises an electroplated copper structure and/or an electroless plated copper structure; and
wherein the pillar portion further comprises a nickel (Ni) barrier layer portion arranged between the solder portion and the pillar portion.

22. The packaged device according to claim 16 wherein the at least one connection structure comprises a layer portion arranged between the solder portion and the pillar portion.

23. The packaged device according to claim 1 wherein the at least one semiconductor device comprises a gallium nitride (GaN) silicon carbide (SIC) transistor.

24. The packaged device according to claim 1 wherein the at least one integrated passive device comprises a silicon carbide (SiC) integrated passive device (IPD).

25. The packaged device according to claim 1 wherein the at least one integrated passive device comprises a printed circuit board (PCB).

26.-38. (canceled)

39. A process of implementing a packaged device comprising:
configuring at least one integrated passive device with at least one bond pad;
configuring at least one semiconductor device with at least one bond pad;
arranging at least one connection structure on the at least one integrated passive device;
arranging a solder portion on the at least one connection structure; and
connecting the at least one connection structure to the at least one bond pad of the at least one semiconductor device with the solder portion.

40. The process of implementing a packaged device according to claim 39 further comprising arranging the solder portion on an end of the at least one connection structure closer to the at least one bond pad of the at least one semiconductor device than the at least one bond pad of the at least one integrated passive device.

41.-82. (canceled)
